(19) United States
(12) Patent Application Publication
(10) Pub. No.: US 2008/0186004 A1
(43) Pub. Date: Aug. 7, 2008

(54) High-Frequency Power MESFET Boost Switching Power Supply

(75) Inventor: Richard K. Williams, Cupertino, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Sunnyvale, CA (US)

(21) Appl. No.: 11/307,200

(22) Filed: Jan. 26, 2006

Related U.S. Application Data
(60) Provisional application No. 60/597,407, filed on Nov. 29, 2005.

(51) Int. Cl. G05F 1/44; H03K 17/687

(52) U.S. Cl. 323/282; 327/431

(57) ABSTRACT

A MESFET based boost converter includes an N-channel MESFET connected to a node Vx. An inductor connects the node Vx to a battery or other power source. The node Vx is also connected to an output node via a Schottky diode or a second MESFET or both. A control circuit drives the MESFET (and the second MESFET) so that the inductor is alternately connected to ground and to the output node. The maximum voltage impressed across the low side MESFET is optionally clamped by a Zener diode. In some implementations, the MESFET is connected in series with a MOSFET. The MOSFET is switched off during sleep or standby modes to minimize leakage current through the MESFET. The MOSFET is therefore switched at a low frequency compared to the MESFET and does not contribute significantly to switching losses in the converter. In other implementations, more than one MESFET is connected in series with a MOSFET, the MOSFETs being switched off during periods of inactivity to suppress leakage currents.

### RELATED APPLICATIONS

This application is one of a group of concurrently filed applications that include related subject matter. The six titles in the group are: 1) High Frequency Power MESFET Gate Drive Circuits, 2) High-Frequency Power MESFET Boost Switching Power Supply, 3) Rugged MESFET for Power Applications, 4) Merged and Isolated Power MESFET Devices, 5) High-Frequency Power MESFET Buck Switching Power Supply, and 6) Power MESFET Rectifier. Each of these documents incorporates all of the others by reference.

### BACKGROUND OF INVENTION

Voltage regulators are used commonly used in battery powered electronics to eliminate voltage variations resulting from the discharging of the battery and to supply power at the appropriate voltages to various microelectronic components such as digital ICs, semiconductor memory, display modules, hard disk drives, RF circuitry, microprocessors, digital signal processors and analog ICs. Since the DC input voltage must be stepped-up to a higher DC voltage, or stepped down to a lower DC voltage, such regulators are referred to as DC-to-DC converters.

Step-down converters are used whenever a battery's voltage is greater than the desired load voltage. Conversely, step-up converters, commonly referred to boost converters, are needed whenever a battery's voltage is lower than the voltage needed to power its load. Step-down converters include transistor current source methods called linear regulators, switched capacitor networks called charge pumps, or by circuit methods where current in an inductor is constantly switched in a controlled manner. Boost converters may be also be made from charge pump switched-capacitor networks or by switched inductor techniques. Switched inductor power voltage regulators and converters are commonly referred to as “switching converters”, “switch-mode power supplies”, or as “switching regulators”. Step-down switching converters using simple inductors, rather than transformers are also referred to as Buck converters.

### Trade-Offs in Switching Regulators

In either step-up or step-down DC to DC switching converters, one or more power switch elements are required to control the current and energy flow in the converter circuitry. During operation these power devices act as power switches toggling on and off at high frequencies and with varying frequency or duration. During such operation, these power devices lose energy to self heating, both during periods of on-state conduction and during the act of switching. These switching and conduction losses adversely limit the power converter's efficiency, potentially create the need for cooling the power devices, and in battery powered applications shorten battery life.

Using today's conventional power transistors as power switching devices in switching regulator circuits, an unfavorable tradeoff exists between minimizing conduction losses and minimizing switching losses. State-of-the-art power devices used in switching power supplies today primarily comprise various forms of lateral and vertical metal-oxide-semiconductor silicon field-effect-transistors or “power MOSFETs”, including submicron MOSFETs scaled to large areas, vertical current flow double-diffused “DMOS” transistors, and vertical trench-gated versions of such DMOS transistors known as “trench FETs” or “trench DMOS” transistors.

Circuit and device operation at higher frequency, desirable to reduce the size of a converter's passive components (such as capacitors and inductors) and to improve transient regulation, involve compromises in choosing the right size power device. Larger lower resistance transistors exhibit less conduction losses, but manifest higher capacitance and increased switching losses. Smaller devices exhibit less switching related losses but have higher resistances and increased conduction losses. At higher switching frequencies this trade-off becomes increasingly more difficult to manage, especially for today's power MOSFET devices, where device and converter performance and efficiency must be compromised to achieve higher frequency operation.

Transistor operation at high frequency becomes especially problematic for converters operating at high input voltages (e.g. above 7V) and those operating at extremely low voltages (e.g. below 1.2 volts). In such applications, optimization of the power device involves even a stricter compromise between resistance and capacitive losses, offering narrower range of possible solutions.

### Conventional Prior-Art DC/DC Converters

FIG. 1 describes a prior art boost-type DC/DC converter used to step-up and produce a higher-voltage regulated output (such as 3.3 volts) from a time varying DC input (such as a 1V NiMH battery). In such switching regulators, the on-time of a power switch is constantly adjusted to regulate the output voltage of the converter despite variations in load current or battery voltage. In fixed frequency converters, the on-time is adjusted by varying, i.e. modulating, the power switch's pulse width. Such converters are referred to as pulse width modulation (PWM) control. PWM controllers are easily modified to operate at variable frequencies, or to switch between fixed and variable modes automatically during low-current load conditions.

In the prior-art embodiment of boost converter shown in circuit 1, the output of PWM control circuit 2 drives gate-buffer 3 which in turn drives the input of N-channel power MOSFET 4. The drain of N-channel MOSFET 4, switched at a high-frequency (typically at 700 kHz or more) controls the average current through inductor 6. Because the inductor forces voltage Vx positive whenever current is interrupted in MOSFET switch 4, the drain of N-channel MOSFET 4 remains more positive than ground, reverse biasing diode 5, so no diode current flows so long that the maximum voltage of the diode and MOSFET is not exceeded. Diode 5 is a PN junction diode intrinsic to power MOSFET 4 antiparallel to the transistor's drain and source terminals, and not an added circuit component. The term “antiparallel” refers to the fact that the diode is connected in parallel with the MOSFET in a polarity where under normal biasing, it remains off.

The drain of N-channel MOSFET 4 is also connected to the output through rectifier diode 7. Whenever the voltage at Vx exceeds Vout, Schottky diode 7 forward-biases and transfers charge to output capacitor 8, boosting the output voltage above the battery voltage. Diode 7 prevents reverse current flow from the output to ground whenever MOSFET 4 is conducting. It may be referred to as a rectifier since it converts AC to DC, specifically where the voltage at node Vx is pulsed DC, i.e. an AC waveform with a DC offset, and the voltage across capacitor 8 is DC (except for some small signal AC noise or ripple).

PWM control 2 and buffer 3 are powered by voltage select circuit 9 comprising Schottky diodes 10 and 11 which acting as a double-throw switch, selects between the battery voltage and the output voltage, whichever is higher. Thus the gate drive for MOSFET switch 4 is powered from the highest possible voltage, i.e. the output voltage, except during the time the converter starts up. Other circuit methods exist to implement the power selector function 9, shown here only as an example. For example, MOSFET or bipolar transistors may be used to perform the power source selector function with less voltage drop than the Schottky diode. Such methods include the use of active switches, e.g. transistors, to replace the Schottky diodes. Alternatively, the circuitry can be permanently powered by the battery input voltage.

During converter operation, feedback from the output of the converter is used to vary the pulse width produced of PWM control circuit 2 to hold the output voltage constant under varying conditions of battery voltage and load current. Capacitor 8 filters high frequency switching noise out of the converter.

Converter 1 suffers from several major deficiencies. The biggest problem with this converter design is that a large low-resistance power MOSFET does not make a good switch when powered by a gate drive of only 1 volt. For alkaline and NiMH batteries the minimum voltage condition fully discharged is actually 0.9V, making it even harder to adequately switch on the power MOSFET. To make the MOSFET switch large enough to exhibit a low on-resistance with so little gate drive requires a very large device having large capacitance and excessive switching losses associated with driving its gate at high frequencies.

Power selector 9 is an attempt to minimize this problem by powering gate drive for MOSFET 4 off of the converter's output after startup. Since Vout is typically 3V or more, it is more suitable to provide sufficient gate drive to the MOSFET. The disadvantage with this approach is the converter suffers lower efficiency. This fact can be understood by recognizing that the converter does not pass all the battery's energy to its output to power its load. Some current is lost to ground and some energy is lost to heat. Depending on the operating current, the maximum current capability of the converter, the MOSFET size, and the switching frequency, converter efficiencies may be a low as 60% and rarely exceed 85%. If the gate drive current, which may be substantial, is powered from the output, the input power to the gate drive already involves additional efficiency loss (compared to powering the switch directly from the battery). The result is that powering the MOSFET from the output is less efficient than the efficiency achievable if an ideal switch driven from a 1V input existed. Unfortunately, conventional silicon MOSFETs do not make good power switches in applications with only one volt of available gate drive.

The limitations of conventional silicon MOSFETs are illustrated in the electrical characteristics of FIG. 2 shown for a variety of on and off conditions. FIG. 2A illustrates the “family of curves” for an N-channel MOSFET showing the drain current I_{D} versus drain-to-source voltage V_{DS} where curves 12, through 15 illustrate curves of increasing gate voltage V_{GS}, for example in one-volt increments. Curve 12 represents the special condition of zero-volt gate drive, i.e. V_{GS}=0, and is often referred to by the nomenclature I_{DSS}. If a device conducts substantially no current under this bias condition, that is if I_{DSS} is small, the device is referred to as an enhancement mode, or “normally-off” type MOSFET. Normally off devices are preferred as switches in most power electronic applications, since their default condition is “off”.

The “turn-on” or threshold voltage Vₜₒ of two different MOSFETs is illustrated in FIG. 2B in the graph of I_{D} versus V_{GS}. MOSFET “A” shown by curve 16 has a higher threshold voltage than MOSFET “B” shown by curve 17. Provided the threshold voltage of either device remains above approximately 0.6V, the avalanche breakdown curve 18 of both devices have an off-state characteristic at V_{GS}=0 as shown in the linear-scale graph of FIG. 2C even in the single-digit microampere range. The log-scale graph of FIG. 2D, however, reveals the lower threshold device B (curve 20) has a different behavior and a comparative basis substantially greater off-state leakage than the higher threshold device A (curve 19), despite the fact that they may exhibit the same avalanche breakdown voltage. This leakage increases with decreasing threshold and increasing temperature, especially for thresholds below 0.6V, making the device unattractive as a normally-off power switch. Beneficially, however, the linear-region on-state resistance, or “on-resistance” for the lower threshold device B is lower than that of the higher threshold device A as shown in the hyperbolic on-resistance curves 22 and 21 respectively in FIG. 2E.

FIGS. 2F and 2G illustrate a fundamental tradeoff in on-state and off-state performance of a MOSFET parametrically as a function of threshold Vₜₒ. In FIG. 2F, on-resistance R_{DS} is shown as a function of threshold voltage Vₜₒ. Curve 23 illustrates the on-resistance of low-threshold device B is less than high-threshold device A, biased under the same gate drive condition, e.g. at V_{GS}=3V.

At a lower gate bias shown by curve 24, e.g. at V_{GS}=1V, not only is the on-resistance increased categorically, but the sensitivity of on-resistance to threshold voltage is greatly increased, where device A has a significantly higher resistance than device B.

FIG. 2G illustrates the threshold dependence of the off-state leakage I_{DSS} Curve 25 illustrates the dependence on leakage as a function of threshold voltage, where device B exhibits higher leakages than device A. Lowering a MOSFET's threshold voltage lead to a rapid increase in leakage current. Clearly a compromise exists between the low leakage of device A and the low on-resistance of device B. To obtain sufficiently low on-resistance for operation with only one-volt of gate drive renders any silicon MOSFET too leaky to use. Raising a MOSFET's threshold by changing its construction also increases the device's on-resistance.

In addition to the tradeoff between leakage and on-resistance, a power MOSFET also exhibits a trade-off between its on-resistance and its switching losses. In devices operating at voltages less than one hundred volts and especially below thirty volts, switching losses are dominated by those losses associated with driving its gate on and off, i.e. charging and discharging its input capacitance. Such gate drive related switching losses are often referred to as “drive losses”. To this point, FIG. 3 illustrates a graph of MOSFET's gate drive voltage V_{GS} versus its on-resistance R_{DS} and on gate charge Q_{G}. Gate charge is a measure of the electrical charge necessary to charge a MOSFET's electrical input capacitance to that specific gate voltage condition. Gate charge is used in preference to predicting a transistor's behavior by capacitance since a MOSFET's capacitances are nonlinear and voltage dependent, especially over the large-signal voltage range used in switching applications. As an integral of voltage and capacitance, gate charge increases in proportion gate bias V_{GS} as illustrated by curve 27. The rapid increase in gate charge at a bias condition of (Vₜₒ+ΔV) shown by region 28 in the gate charge curve is due to charging of the MOSFET's gate to drain overlap capacitance when the device switches from off to on.

In contrast to gate charge increasing in proportion gate bias V_{GS}, curve 26 illustrates on-resistance decreases with increasing gate bias. The product of gate charge and on-resistance, or Q_{G}·R_{DS}, as shown by curve 28 in FIG. 3 exhibits a minimum value at some gate bias above the MOSFET's threshold. This minimum exemplifies the intrinsic trade-off between conduction losses (arising from on resistance) and switching losses (arising from driving the transistor's gate) in a power MOSFET. Overdriving the gate to higher voltages decreases on-resistance but increases gate charge and gate drive losses. Inadequate gate drive leads to large increases in on-resistance, especially below or near threshold voltage.

Minimizing the Q_{G}·R_{DS} product of a silicon MOSFET is difficult since changes intended to improve gate charge tend to adversely impact on-resistance. For example, doubling a transistor's size and gate width will (at best) halve its on-resistance but double its gate charge. The resulting Q_{G}·R_{DS} product is therefore unchanged, or in some cases even increased.

Designing a transistor to exhibit low on-resistance at low gate voltages, e.g. 1V, requires low threshold voltages which in turn requires the use of thinner gate oxides. Thinning the gate oxide however, not only limits the maximum safe gate voltage, but increases gate charge. The resulting device remains un-optimized for high frequency power switching applications.

### Using Other Semiconductor Materials

The compromises involving gate charge, on resistance, breakdown, and off leakage in power MOSFETs previously described represent physical phenomena fundamentally related to the semiconductor material itself, in this case silicon. If we consider these limitations as an intrinsic property of the silicon material itself, then an alternative approach to realize a low-voltage high frequency power transistor switch may employ non-silicon semiconductor materials. While silicon carbide, semiconducting diamond, and indium phosphide may hold some promise to meet this need in the future, the only material sufficiently mature for practical application today is gallium arsenide, or GaAs.

GaAs has to date however only been commercialized for use in high-frequency and small signal applications like radio frequency amplifiers and RF switches. Historically, its limited use is due to a variety of issues including high cost, low yield, and numerous device issues including fragility, and its inability to fabricate a MOSFET or any other insulated gate active device. While cost and yield issues have diminished (somewhat) over the last decade, the device issues persist.

The greatest limitation in device fabrication results from its inability to form a thermal oxide. Oxidation of gallium arsenide leads to porous leaky and poor quality dielectrics and unwanted segregation and redistribution of the crystal's binary elements and stoichiometry. Deposited oxides, nitrides, and oxy-nitrides exhibit too many surface states to be used as a MOSFET gate dielectric. Without any available dielectric, isolation between GaAs devices is also problematic, and has thwarted many commercial efforts to achieve higher levels of integration prevalent in silicon devices and silicon integrated circuits.

These issues aside, one approach successfully used to make a prior art GaAs field-effect transistor without the need for a gate oxide or high temperature processing is the metal-epitaxial-semiconductor field-effect transistor, or MESFET as shown in FIG. 4A. In cross section 30, the transistor is fabricated in a GaAs mesa 32 formed atop semi-insulating GaAs substrate 31. The device is isolated by an etched mesa to separate each device from adjacent devices prior to die separation in manufacturing. Rather than implanting and annealing dopant to form N+ regions 34, the N+ layer is grown as part of the epitaxial process used to form N− epitaxial layer 33.

The device uses a Schottky metal gate 36 formed in a shallow etched trench 35 and contact by metal electrode 38. The gate trench is etched sufficiently deep to transect N+ layer 34 into two sections, one acting as the transistor's source contacted by source metal 39, the other acting as its drain and contacted by metal 37. The Schottky metal is typically a refractory metal, typically titanium, tungsten, cobalt, or platinum chosen for the electrical properties of the junction it forms with N− GaAs layer 33. In prior art structures, the Schottky gate barrier metal 36 is located entirely inside the trench and spaced from the trench sidewall to avoid any contact with N+ layer 34. Contact between the Schottky gate and said N+ layer will result in unacceptably high gate leakage and impair the device's normal operation. The interconnect metal is chosen to make an ohmic contact with both N+ layer 34 and the Schottky gate material 36. Gold is one common interconnect material used in MESFET fabrication. Contact to the Schottky gate 36 by metal 38 occurs inside the trench, specifically where Schottky metal 36 sits atop of and extends beyond interconnect metal 38. Metal 38 does not contact epi layer 33 in the bottom of the trench.

Operation of device 30 is unipolar, where the depletion region formed by the Schottky barrier between gate material 36 and epi layer 33 is influenced by the gate potential of electrode 38, and modulates the electron flow between source 37 and drain 39. The gate 36 transects the entire mesa 32 to prevent any N+ surface leakage currents. All current must therefore flow beneath trench 35, modulated by the depletion region of the Schottky junction. Since no current is intentionally injected into the gate, the device operates as a field effect transistor, as depicted in FIG. 4B as the same schematic element 40 used for a JFET, except that the gate is Schottky and not a diffused junction. As a unipolar device, carrier transport is entirely majority carrier with no stored charge, making the device suitable for high frequency operation.

During operation, no substantial current flows through the semi-insulating substrate 31, although a buffer layer sandwich of multiple alternating materials or junctions may be grown as an interface between substrate 31 and epi layer 33 to further reduce substrate leakage.

FIG. 4C illustrates the family of curves for a conventional MESFET which we shall here denote as a “type B” device. Curve 40 illustrates the drain current that results from operating the devices with its gate shorted to its source, i.e. V_{GS0}=0. The non-zero I_{DSS} current indicates that the device is normally on, otherwise known in MOSFET vernacular as “depletion mode”. Curve 41, 42, and 43 at increasing positive gate biases of V_{GS1}, V_{GS2}, and V_{GS3} respectively illustrates that the drain current is increased by slightly forward biasing the gate electrode. The gate can only be forward biased to the voltage at which the Schottky junction becomes forward biased and the depletion region shrinks to its minimum extent. Beyond V_{GS3}, the gate-to-source voltage becomes clamped at the Schottky's forward voltage, typically 0.7 to 0.9V. The compressed spacing between the family-of-curves, e.g. between curves 42 and 43, illustrate that beyond some bias additional forward biasing of the gate produces diminishing benefits in device conductivity. Excessive forwarding biasing of the Schottky junction at high current densities may also permanently damage the device.

FIG. 4C also illustrates that the drain current can be suppressed below l_{DSS} by further reverse biasing the Schottky junction, i.e. by applying a negative gate-to-source bias as depicted by curves 44, 45, and 46 operated at gate potentials −V_{GS4}, −V_{GS5}, −V_{GS6} respectively. The reduced current results from the increased pinching of the drain current under the gate by the reverse biased depletion region. The compressed spacing between the family of curves, e.g. between curves 45 and 46 illustrates that further increases in reverse gate bias result in diminishing benefits in suppressing drain current. Note that the maximum extent of the depletion region may be unable to pinch-off the drain current totally, in which case the device cannot be fully turned off. Such a device, where the minimum drain leakage I_{Dmin} is substantially above zero, does not make a useful power switch. An alternate description of a depletion mode transistor is one where I_{DSS}>I_{Dmin}, i.e. where the zero biased gate is far above the minimum achievable leakage current.

### SUMMARY

The present invention relates to boost converters that are preferably, but not necessarily based on the type of MESFET described in the US patent application entitled “Rugged MESFET for Power Application.” This type of MESFET, referred to in this document as a “Type A” MESFET is a normally off device with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). These characteristics make Type A MESFETs particularly suitable as power switches in Boost converters, Buck converters, Buck-boost converters, flyback converters, forward converters, full-bridge converters, and more.

One type of MESFET-based boost converter uses an inductor and N-channel MESFET connected in series between a battery (or other power source) and ground. The N-channel MESFET is driven by a specialized gate buffer that provides unique drive properties matched to the MESFET. Suitable implementations for the gate buffer are described in the copending U.S. patent application: “High Frequency Power MESFET Gate Drive Circuits.” For the purposes of description, it is assumed that a node Vx is located between the inductor and MESFET. Importantly, the low drive requirements of the MESFET allow the gate buffer to be powered from the battery and not from the output of the converter. A Zener diode is optionally connected between the node Vx and ground to protect the MESFET from over-voltage conditions. The Zener diode must be in close proximity to the MESFET, and should ideally be in the same package. A Schottky diode connects the node Vx to an output node. An output capacitor is connected between the output node and ground.

During operation, the MESFET is enabled and disabled under control of a PWM circuit, which may operate in constant frequency pulse-width-modulation (PWM) mode or may operate in a variable frequency or pulse frequency mode (PFM) (or in any mixture of PWM and PFM). The PWM circuit is powered by a voltage selector circuit which draws its power from the battery or from the output, whichever one is greater in voltage. When the MESFET is enabled, current flows through the inductor storing energy as a magnetic field. When the MESFET is disabled, the inductor and battery are connected in series to the output node. As a result, current flows to the output node and the output node is held at greater than battery voltage as the inductor discharges.

A second type of MESFET-based boost converter replaces the Schottky diode in the converter just described with a second N-channel MESFET driven by a gate buffer. The gate buffer for the second N-channel MESFET may be a conventional CMOS buffer or alternatively may provide a floating gate drive with higher potential than the battery voltage or with unique drive properties matched to the MESFET. Suitable gate buffer circuits are described in the copending U.S. patent application: “High Frequency Power MESFET Gate Drive Circuits.” A Schottky diode is connected in parallel with the MESFET of the second N-channel MESFET. The Schottky diode provides a conduction path between the inductor and capacitor whenever the voltage at the node Vx exceeds the voltage at the output node, i.e. when the main MESFET switch is off. A break-before-make (BBM) circuit is added to the PWM circuit to prevent both the condition where both MESFETs are enabled simultaneously. As a variation of this design, the second N-channel MESFET may be replaced with an N or P-channel MOSFET.

Both of the boost converters described are capable of operation at high switching frequencies. At switching frequencies of 1 MHz, inductor L can be selected to be approximately 5 μH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

### Low-Leakage Cascode Power MESFET-MOSFET Switch

To improve the performance of MESFET based-boost converters, it is possible to replace the main (i.e., low-side) N-channel MESFET with a series connection of an N-channel MESFET and some other switch, such an N-channel MOSFET. The MOSFET has much lower off-state leakage current and higher off-state resistance than the MESFET but is more costly in power consumption to switch at high frequencies. This tradeoff in capabilities can be used advantageously by switching the MOSFET off to prevent leakage during standby or sleep-mode operation or during any other long duration of inactivity and holding the MOSFET on whenever the MESFET is switching. Several possible permutations of this design are possible. For the first, a cascode switch is established with a drain node connected to an N-channel MESFET. The MESFET is connected to an N-channel MOSFET that is connected to the source node of the cascode. A second permutation reverses the ordering of the MESFET and MOSFET so that the MOSFET is connected to the cascode drain and the MESFET is connected to the cascode source. Alternately, either of these configurations may be produced using P-channel MOSFETs.

The drive characteristics of MESFETs and MOSFETs are different. As a result, it will generally be the case that switching converters will include separate gate buffers for the MOSFET and MESFET whenever a cascode switch is used. The signal used to control the MOSFET's gate is also different than the one controlling the MESFET's gate, both in frequency and in their purpose.

### Protected Cascode MESFET-MOSFET Switch

To prevent unwanted avalanche breakdown and hot-carrier generation the maximum voltage present over a MESFET must never be allowed to approach the avalanche point, even in during a momentary voltage transient. For this reason, it is desirable to place a Zener diode in parallel with the MESFET in each of the cascode switches just described. Alternately, the cascode switches may be constructed with the Zener diode in parallel with the combination of MESFET and MOSFET.

### Cascode MESFET-MOSFET Boost Converters

The cascode switches just described may be used to produce highly efficient boost converters. A representative implementation of a converter of this type uses an inductor and a cascode switch connected in series between a battery (or other power source) and ground. The N-channel MESFET of the cascode switch is driven by a specialized gate buffer that provides unique drive properties matched to the MESFET. Suitable implementations for the gate buffer are described in the copending U.S. patent application: “High Frequency Power MESFET Gate Drive Circuits.” For the purposes of description, it is assumed that a node Vx is located between the inductor and MESFET. Importantly, the low drive requirements of the MESFET allow the gate buffer to be powered from the battery and not from the output of the converter. A Zener diode is optionally connected between the node Vx and ground to protect the MESFET from over-voltage conditions. The Zener diode must be in close proximity to the MESFET, and should ideally be in the same package. A Schottky diode connects the node Vx to an output node. An output capacitor is connected between the output node and ground. Importantly, the cascode switch may be any of the permutations described previously, including both N and P-channel types.

A second type of MESFET-based boost converter replaces the Schottky diode in the converter just described with a second N-channel MESFET driven by a gate buffer. The gate buffer for the second N-channel MESFET may be a conventional CMOS buffer or alternatively may provide a floating gate drive with higher potential than the battery voltage or with unique drive properties matched to the MESFET. Suitable gate buffer circuits are described in the copending U.S. patent application: “High Frequency Power MESFET Gate Drive Circuits.” A Schottky diode is connected in parallel with the MESFET of the second N-channel MESFET. The Schottky diode provides a conduction path between the inductor and capacitor whenever the voltage at the node Vx exceeds the voltage at the output node, i.e. when the main MESFET switch is off. A break-before-make (BBM) circuit is added to the PWM circuit to prevent both the condition where both MESFETS are enabled simultaneously.

Additional variations on the MESFET based switching regulators described above are possible. If every switching regulator is assumed to include a low-side switch and a high-side switch the following combinations are possible:
1. low-side switch: Schottky diode, high-side switch: N-channel MESFET.
2. low-side switch: Schottky diode, high-side switch: MESFET cascode switch.
3. low-side switch: N-channel MESFET, high-side switch: Schottky diode
4. low-side switch: N-channel MESFET, high-side switch: N-channel MESFET.
5. low-side switch: N-channel MESFET, high-side switch: MESFET cascode switch.
6. low-side switch: N-channel MESFET, high-side switch: MOSFET.
7. low-side switch: MOSFET, high-side switch: N-channel MESFET.
8. low-side switch: MOSFET, high-side switch: MESFET cascode switch.
9. low-side switch: MESFET cascode switch, high-side switch: Schottky diode
10. low-side switch: MESFET cascode switch, high-side switch: MOSFET.
11. low-side switch: MESFET cascode switch, high-side switch: N-channel MESFET.
12. low-side switch: MESFET cascode switch, high-side switch: MESFET cascode switch.
13. Of these various circuit topologies, combinations (1) and (2) are uniquely suitable for Buck converters while (3) and (9) are dedicated to boost converters. While the remaining combinations may be used for Buck, boost, or the combination of Buck and boost (i.e. Buck boost) converters, those employing MOSFETs as a high speed switch, namely topologies (6), (7), (8), and (10) will suffer efficiency degradation at higher switching frequencies and are therefore contraindicated. In the application of topologies (3) to (12) in realizing a boost converter, the low-side switch functions as the switch controlling the energy input into the converter, while the high-side switch acts a synchronous rectifier to prevent backflow of energy from the converter's output filter capacitor to ground.

### DESCRIPTION OF FIGURES

FIG. 1 Boost switching converter using power MOSFET switch (Prior Art).

FIG. 2 Power MOSFET electrical characteristics. (A) family of drain curves (B) gate dependence of drain current for high and low Vt devices (C) avalanche breakdown characteristics (D) drain leakage (log scale) for high and low Vt devices (E) gate dependence of on-resistance for high and low Vt devices (F) threshold dependence of on-resistance (G) threshold dependence of drain leakage.

FIG. 3 V_{GS} dependence of power MOSFET gate charge and on-resistance.

FIG. 4 GaAs MESFET cross section and electrical characteristics. (A) prior-art cross section (B) symbol (C) “type B” prior-art family-of-curves (D) hypothetical “type A” family-of-curves (E) gate characteristics (F) gate dependence of on resistance for two device types.

FIG. 5 MESFET DC/DC boost converters. (A) boost converter (B) synchronous boost converter.

FIG. 6 Various MESFET-MOSFET cascode switch characteristics. (A) N-channel series circuit (B) off-state leakage characteristics (C) cascode and MESFET on-state resistance (D) inverted N-channel series circuit (E) P-channel MOSFET version (F) inverted P-channel MOSFET version.

FIG. 7 Avalanche and leakage mechanisms in normally-off (enhancement mode) MESFET.

FIG. 8 Zener clamped MESFET switches. (A) quadrant I current-voltage characteristics (B) equivalent clamped MESFET circuit (C) N-channel series circuit with MESFET clamp (D) N-channel series circuit with antiparallel clamp (E) P-channel MOSFET series circuit with MESFET clamp (F) P-channel MOSFET series circuit with N-channel MESFET and antiparallel clamp.

FIG. 9 Cascode MOSFET-MESFET boost converter with low-side N-channel Switch.

FIG. 10 Cascode MOSFET MESFET boost converter with floating N-channel Switch.

FIG. 11 MESFET synchronous boost converter.

FIG. 12 cascode MESFET MOSFET synchronous boost converter with low side switch.

FIG. 13 cascode MESFET MOSFET synchronous boost converter with floating switch.

FIG. 14 MESFET synchronous boost converter with P-channel high-side switch.

FIG. 15 MESFET synchronous rectifier gate drive circuit.

FIG. 16 cascode MESFET MOSFET boost converter with P-channel MOSFET synchronous rectifier.

### DESCRIPTION OF INVENTION

The present invention includes inventive matter regarding the use of a proposed power MESFET in switching power supplies. The proposed power MESFET is referred to in this document as a “type A” device. Before describing the use of the “type A” device in switching power supplies, a short description of the “type A” device is presented. A more complete description of the “type A” device and its applications is included the related patent applications previously identified.

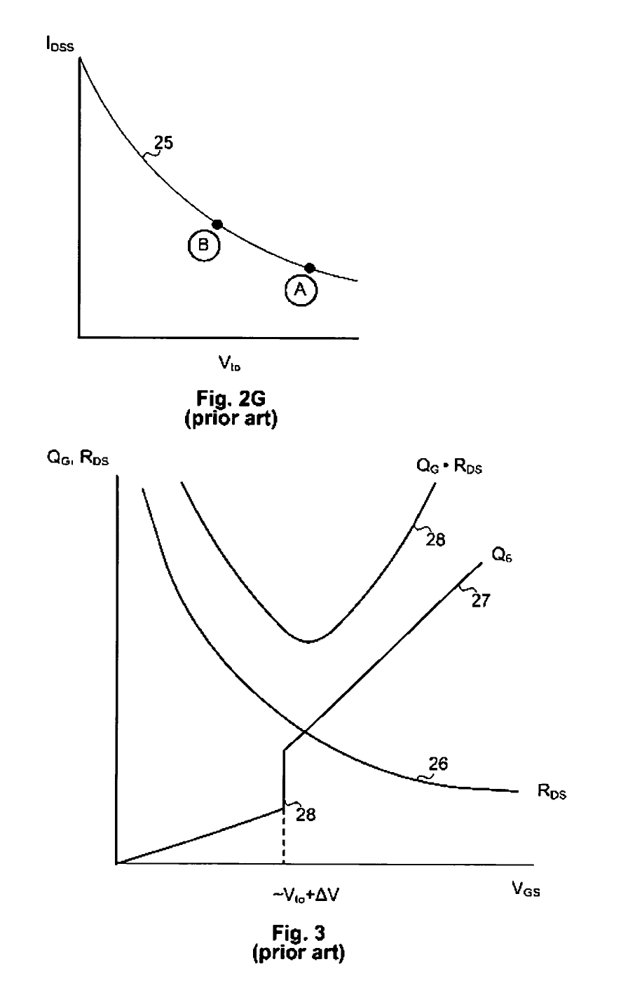

FIG. 4D illustrates how the previously described “type B” depletion-mode device would need to be adjusted to make a power switch with useful characteristics (i.e., the “type A” device). Similar to an enhancement mode MOSFET, the proposed “type A” MESFET needs to exhibit a near zero value of I_{DSS} current, i.e. the current I_{Dmin} shown as line 50 should be as low as reasonably possible at V_{GSO}=0, i.e. where I_{DSS}≈I_{Dmin} Biasing the Schottky gate with positive potentials of V_{GS1}, V_{GS2}, and V_{GS3} results in increasing currents 51, 52, and 53, respectively, clamped to some maximum value by conduction current in the Schottky gate. There is no need to apply negative gate bias to such a device.

The range in gate voltages V_{GS} that a MESFET may be operated is, unlike an insulated gate device or MOSFET, bounded in two extremes as shown in FIG. 4E. In the direction of forward bias as shown by curve 60 the maximum gate bias is V_{F}, the forward bias voltage of the Schottky at the onset of conduction. In the reverse direction, line 61 represents the Schottky avalanche voltage. Extreme bias conditions, whether forward or reverse biased can damage the fragile MESFET. Moreover, driving the MESFET gate into forward conduction leads to DC power losses from gate conduction, adversely impacting the efficiency of power converters using the device.

FIG. 4F illustrates a theoretical comparison of the linear region on-resistance of the two MESFET types as a function of V_{GS}. The less leaky proposed “type A” device is expected to exhibit a higher resistance than the normally on “type B” device.

Ideally then, a power switch suitable for very high-frequency DC/DC conversion a normally off device with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). Such a power device will then be capable of operating at high frequencies with low drive requirements, low switching losses, and low on-state conduction losses. Implementing such a power switch using a MESFET such as the GaAs MESFET previously described, a MESFET must be substantially modified in its fabrication and its use, and may require changes in its fabrication process, mask layout, drive circuitry, packaging, and its need for protection against various potentially damaging electrical conditions.

### Power MESFET Boost Converter

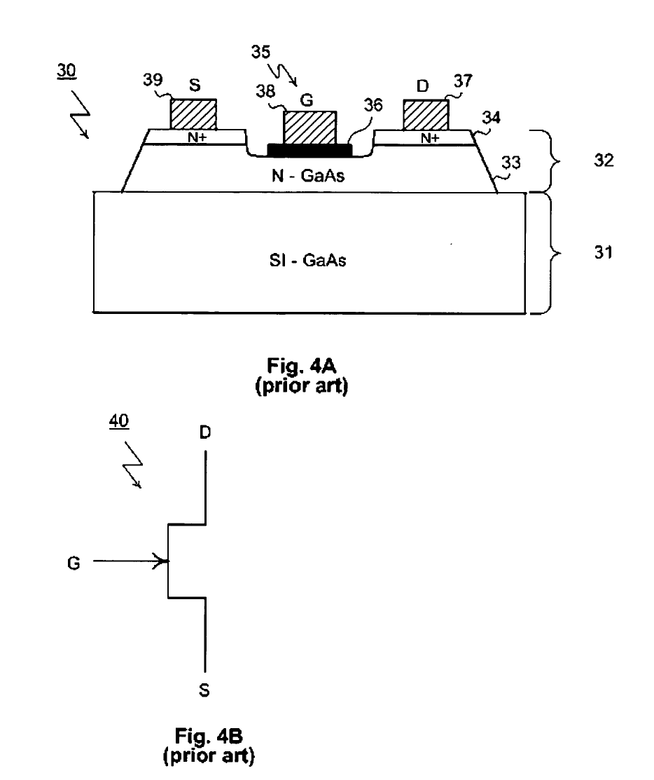

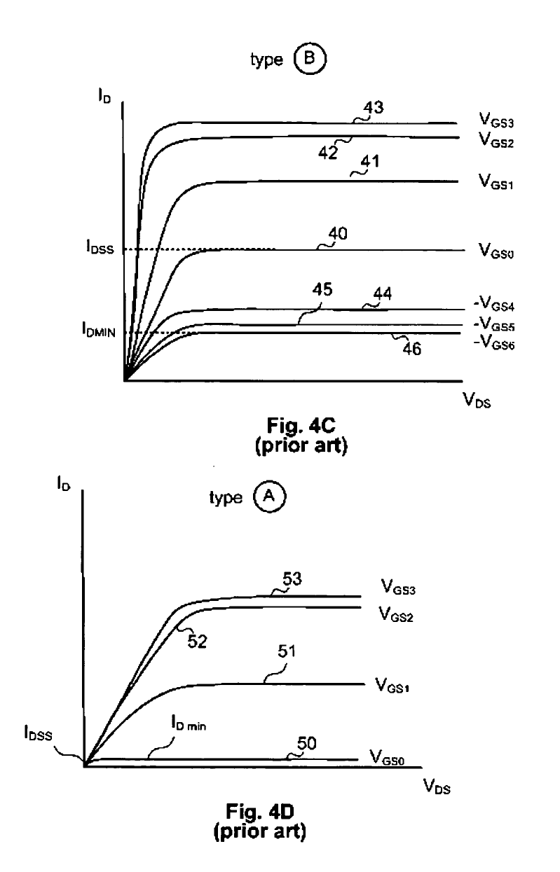

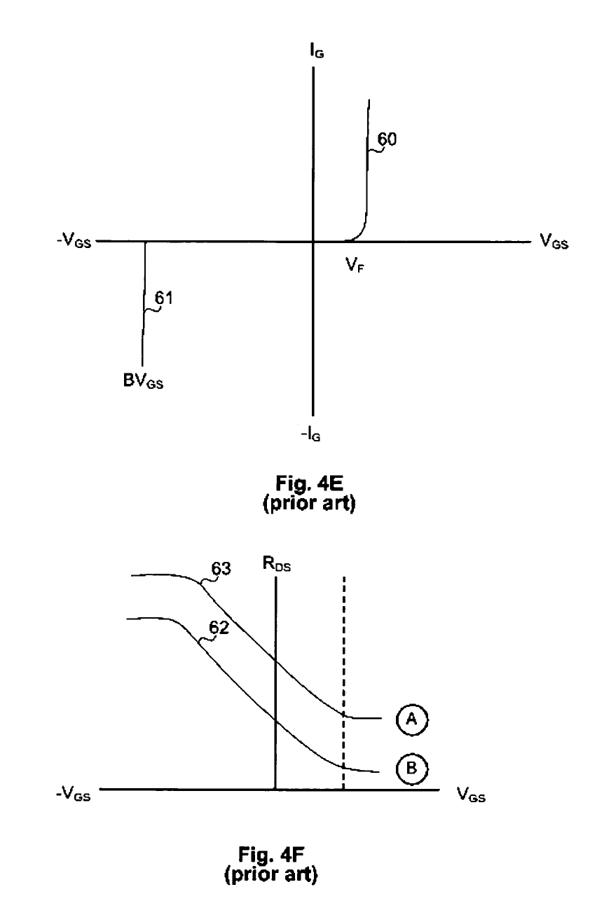

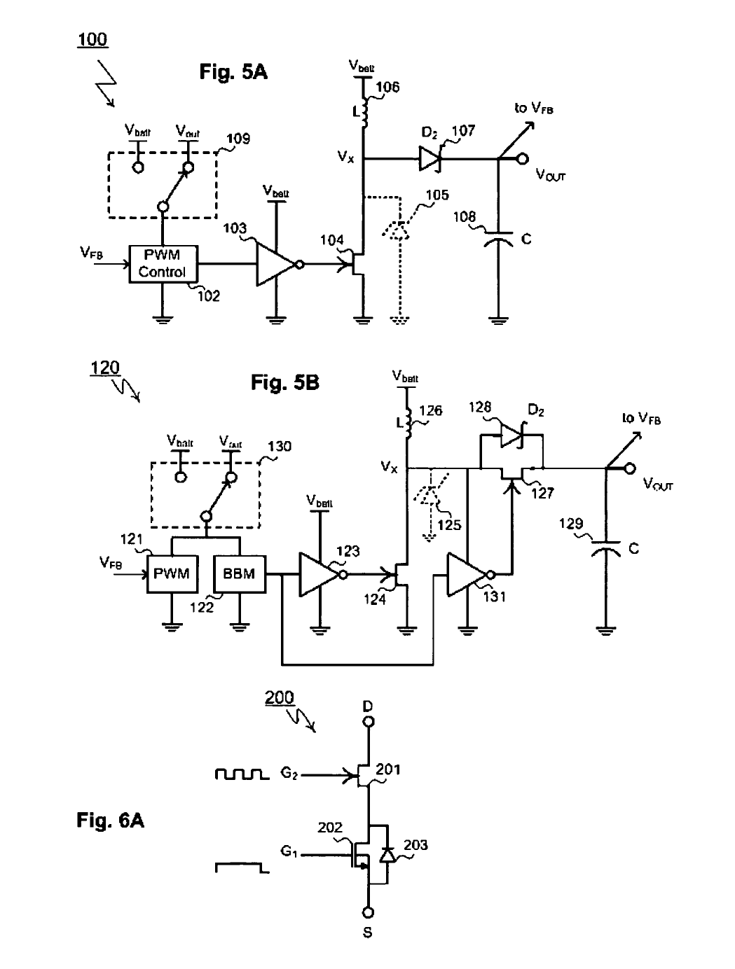

FIG. 5A illustrates an inventive boost converter using a MESFET as the power switch. In this example power MESFET 104 is switched at a high frequency by gate buffer 103 powered directly from the battery. The on-time, duty factor and switching frequency of power MESFET 104 is controlled by PWM circuit 102, where said PWM circuit may operate in constant frequency pulse-width-modulation (PWM) mode or may operate in a variable frequency or pulse frequency mode (PFM). PWM circuit 102 is powered by voltage selector circuit 109, which draws its power from the battery or from the output, whichever one is greater in voltage.

Voltage boosting is achieved by switching current in inductor 106. Whenever the voltage Vx rises above the output voltage, Schottky diode 107 conducts delivering power to the load and to charge output filter capacitor 108. Zener diode 105 is optionally available to provide protection against over-voltage conditions damaging the MESFET switch. At switching frequencies of 1 MHz, inductor L can be selected to be approximately 5 μH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

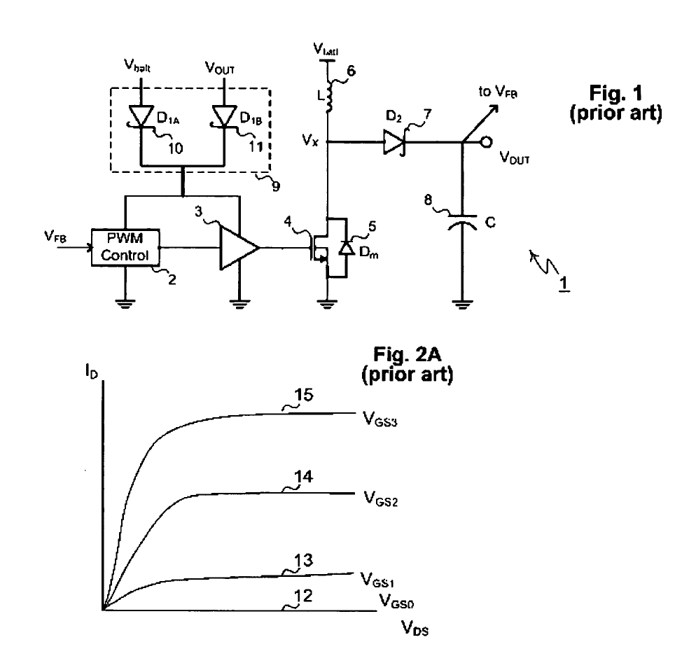

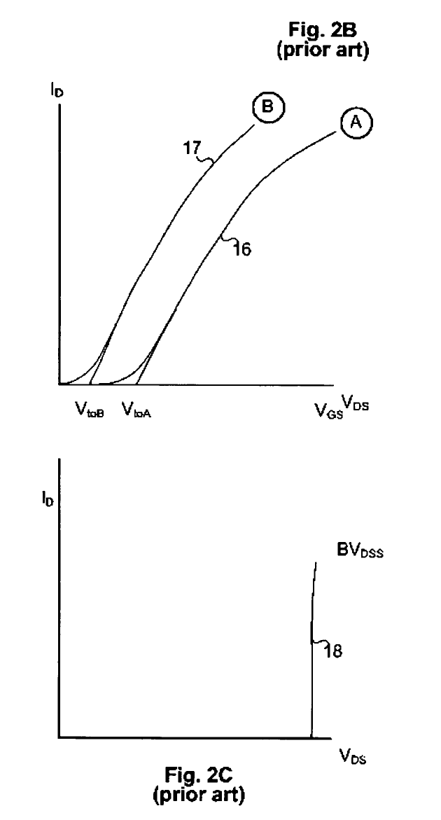

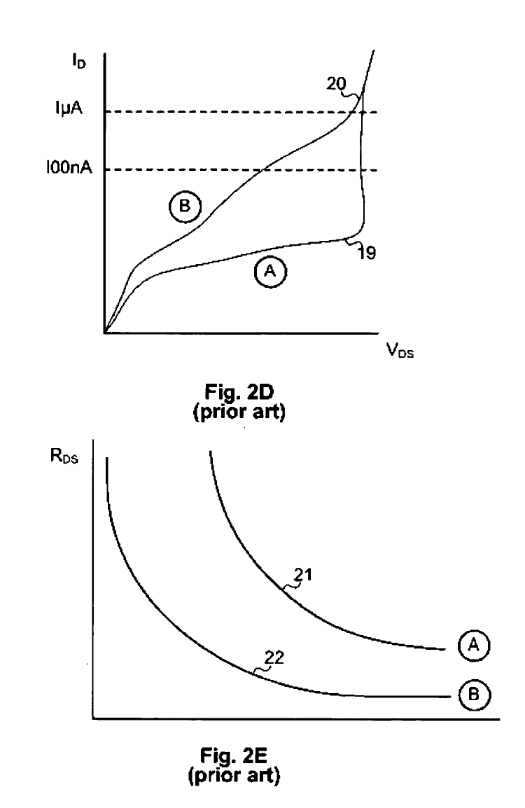

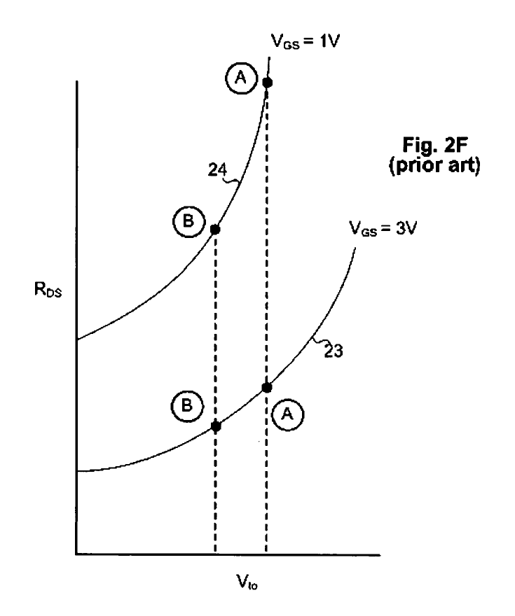

The importance of Zener diode 105 in limiting the maximum drain voltage Vx across MESFET 104 is unique to the MESFET based boost converter. Using a MOSFET (like in circuit 1 of FIG. 1), noise spikes across the switching device can be absorbed by the MOSFET's intrinsic P-N drain-to-source junction. The MESFET, however, being unipolar in construction, has no intrinsic P-N junction to act as a voltage clamp and gives rise to the device's deficiency in avalanche ruggedness. In such cases the importance to clamp voltage Vx is critical in avoiding device damage.

Theoretically, diode 107 should clamp the drain voltage of MESFET 104 to Vx≦(Vₒᵤₜ+V_{F}) and protect the device. In practice, however, the presence of stray inductance in the drain of MESFET 104 can cause Vx to spike to higher voltages for short durations before diode 107 has time to react. Clamp diode 105 must be in close proximity to MESFET 104 to avoid the same issue, and ideally should be in the same package. It would be even more ideal to integrate clamp diode 105 into MESFET 104, but since GaAs fabrication has difficulty in forming P-type regions, that challenge and the practical realization thereof is beyond the scope of this disclosure.

Gate drive buffer block 103 drives the Schottky gate input of MESFET 104. Gate buffer 103 is not just a conventional CMOS gate buffer, but must provide unique drive properties matched to MESFET 104. Failure to properly drive MESFET 104 can lead to noisy circuit operation and increased conduction losses if MESFET 104 is supplied with inadequate gate drive, i.e. where the current capability of buffer 103 is too low to charge the input capacitance of MESFET in the time required for high frequency operation, or that the output voltage of buffer 103 is too low to fully turn-on MESFET 104 into a low-resistance fully conductive operating state. Conversely, in the event that gate buffer 103 drives the gate of MESFET 104 at too high of current or too much voltage, the resulting high gate current can lead to excessive power loss, localized heating, oscillations, and even device damage. Gate buffer 103 must rapidly drive MESFET gate 104 to the proper on-state bias condition without underdriving or overdriving the device during switching transitions.

Note also that in boost converter circuit 100, gate buffer 103 and the source of MESFET 104 share a common ground connection, which in the example shown is the most negative DC potential in the circuit and typically represents the negative terminal of the battery in portable electronics. Gate buffer 103 may be inverting or non-inverting.

FIG. 5B illustrates an inventive synchronous boost converter using a MESFET as the converter's main power switch and another MESFET as a synchronous rectifier. In this example power MESFET 124 is switched at a high frequency by gate buffer 123 powered directly from the battery. The on-time, duty factor and switching frequency of power MESFET 124 is controlled by PWM circuit 121, where said PWM circuit may operate in constant frequency pulse-width-modulation (PWM) mode or may operate in a variable frequency or pulse frequency mode (PFM). PWM circuit 121 is powered by voltage selector circuit 130, which draws its power from the battery or from the output, whichever one is greater in voltage.

Voltage boosting is achieved by switching current in inductor 126. Whenever the voltage Vx rises above the output voltage, N-channel power MESFET 127 conducts delivering power to the load and to charge output filter capacitor 129. Zener diode 125 is optionally available to provide protection against over-voltage conditions damaging the MESFET switch 124. Above switching frequencies of 1 MHz, inductor L can be made small similar to circuit 100 of FIG. 5A.

Break before make (BBM) circuit 122 provides deadtime protection to prevent both the main switch (comprising power MESFET 124), and the synchronous regulator (comprising MESFET 127) from conducting simultaneously and shorting out capacitor 129. Schottky diode 128 provides a conduction path between inductor 126 and capacitor 129 whenever Vx exceeds Vout, i.e. when main MESFET switch 124 is off.

Gate drive buffer block 123 drives the Schottky gate input of MESFET 124. Gate buffer 123 is not just a conventional CMOS gate buffer, but must provide unique drive properties matched to MESFET 124. Failure to properly drive MESFET 124 can lead to noisy circuit operation and increased conduction losses if MESFET 104 is supplied with inadequate gate drive, i.e. where the current capability of buffer 123 is too low to charge the input capacitance of MESFET in the time required for high frequency operation, or that the output voltage of buffer 123 is too low to fully turn-on MESFET 124 into a low-resistance fully conductive operating state. Conversely, in the event that gate buffer 123 drives the gate of MESFET 124 at too high of current or too much voltage, the resulting high gate current can lead to excessive power loss, localized heating, oscillations, and even device damage. Gate buffer 123 must rapidly drive MESFET gate 124 to the proper on-state bias condition without underdriving or overdriving the device during switching transitions.

Note also that in boost converter circuit 120, gate buffer 123 and the source of MESFET 124 share a common ground connection, which in the example shown is the most negative DC potential in the circuit or the negative terminal of a battery. Gate buffer 123 may be inverting or non-inverting.

Gate drive buffer block 131 drives the Schottky gate input of synchronous rectifier MESFET 128. Gate buffer 131 may be a conventional CMOS buffer or alternatively may provide a floating gate drive with higher potential than the battery voltage or with unique drive properties matched to MESFET 127. Failure to properly drive MESFET 127 can lead to noisy circuit operation and increased conduction losses if MESFET 127 is supplied with inadequate gate drive, i.e. where the current capability of buffer 131 is too low to charge the input capacitance of MESFET in the time required for high frequency operation, or that the output voltage of buffer 131 is too low to fully turn-on MESFET 127 into a low-resistance fully conductive operating state. Conversely, in the event that gate buffer 131 drives the gate of MESFET 127 at too high of current or too much voltage, the resulting high gate current can lead to excessive power loss, localized heating, oscillations, and even device damage. Gate buffer 131 must rapidly drive floating MESFET gate 127 to the proper on-state bias condition without underdriving or overdriving the device during switching transitions.

Without a floating gate drive circuit, the minimum voltage drop and maximum conductance of MESFET 127 occurs only when its gate is connected to node Vx through gate buffer 131. While this voltage drop may be less than a Schottky diode, it is not as low as a synchronous rectifier with floating gate drive.

Operation of a DC-to-DC switching converter as shown in circuits 100 and 120 using a normally-off power MESFET switch are capable of high-efficiency operation at multi-MHz frequencies because of the device's low on-resistance, low gate charge, and low turn-on (threshold) voltage. The performance benefit is especially beneficial in 1V and single dry cell applications where other semiconductor switches suffer poor performance and high on-resistance.

### Low-Leakage Cascode Power MESFET-MOSFET Switch

In battery powered applications, it is often necessary to place the converter into standby or sleep mode where it may remain for days or even weeks without being operated. In such situations even the slightest off-state leakage, leakages in the range of a few microamperes can shorten standby time by continuously “bleeding” the battery dry through a low current discharge. Any current which discharges the battery faster than the natural electrochemical discharge rate of the battery represents a theoretical loss in performance and an opportunity for improving battery life.

This type of leakage problem is manifest in converter 100 of FIG. 5A since there is no means to prevent leakage from the battery to ground through inductor 106 and MESFET 104. In its off state, MESFET 104 still leaks drain current, possibly in the microampere range, and slowly discharges the battery powering its input.

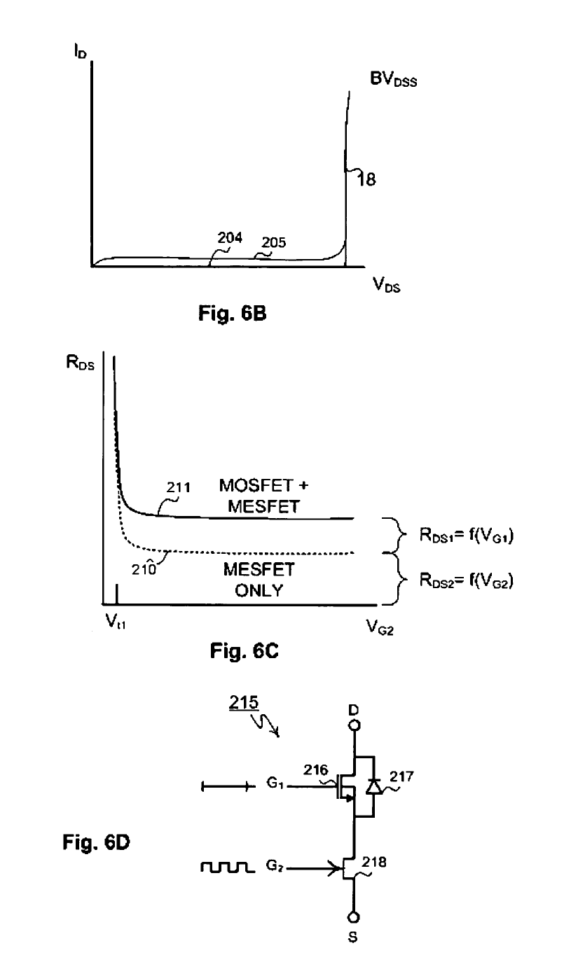

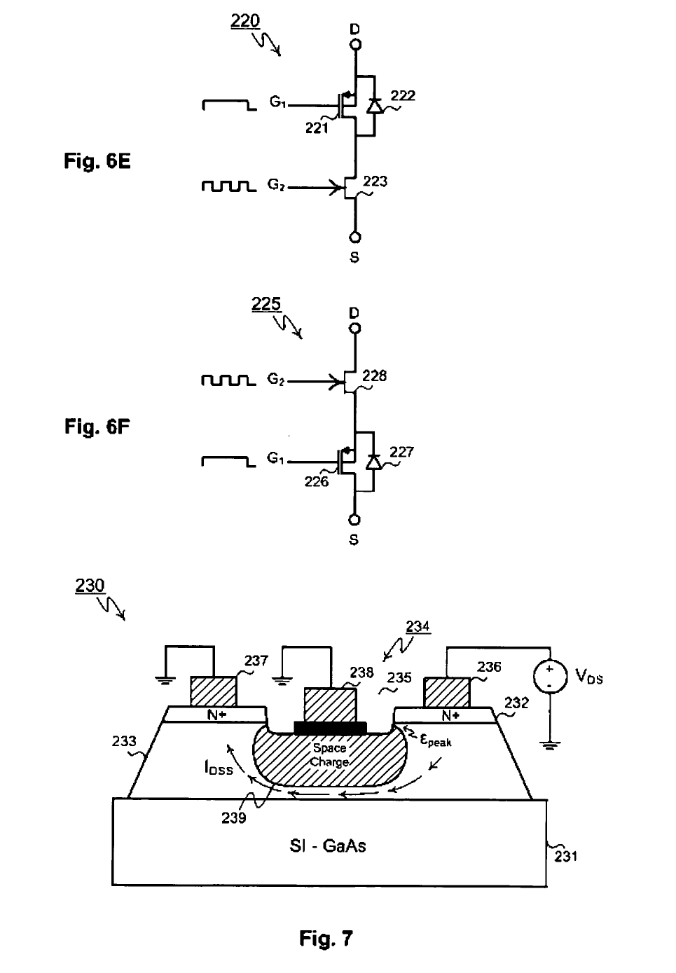

FIG. 6A illustrates a method to eliminate this unwanted leakage through a cascode configured switch 200 comprising MESFET 201 and series connected MOSFET 203 further containing drain-source intrinsic diode 203. MESFET 201 can, for example, be made of GaAs while MOSFET 202 can be made of silicon. Since silicon and GaAs wafer fabrication are generally incompatible, the two die can be assembled together in a multi-die or stacked-die package.

FIG. 6B illustrates compares the leakage property of the MESFET and MOSFET cascode combination. Whenever MOSFET 202 is off, the leakage property of the cascode device 200 is very low, approaching zero on linear scale graph as shown by curve 204. Whenever MOSFET 202 is turned on in preparation for converter operation, the switch leakage shown by curve 205 is that of the MESFET 201. To apply this switch in a DC-to-DC boost converter, MESFET 201 is switched at a high frequency whenever MOSFET 202 is held on. MOSFET 202 is only turned off after longer periods of inactivity, for example whenever the converter doesn't operate for over one or even several seconds. Since MOSFET 202 is not being switched at a high frequency, its does not substantially contribute to the overall capacitance, gate charge, or switching losses of the cascode device.

It should be noted that the BV_{DSS} of the combined cascode device. Ideally this device should have a blocking voltage equal to the sum of the breakdown voltages of MESFET 201 and MOSFET 202, i.e. the breakdown of intrinsic diode 203. Since the two series devices form a capacitor divider, however, it is possible during rapid transients to force the MESFET 201 into temporary transient breakdown, which may damage the device. Without adding some extra voltage clamp, it is prudent to choose MOSFET 202 to have a breakdown higher than that of MESFET 201. In converter applications, MOSFET 202 (with its intrinsic drain-to-body diode 203) should have a breakdown greater than the maximum voltage expected across the switch. In a boost converter application this minimum breakdown voltage should exceed the output voltage by a forward-biased diode drop plus some guardband. In a Buck converter the MOSFET's avalanche voltage need only exceed the battery input voltage (plus some guardband for noise).

Curve 210 in FIG. 6C illustrates the on-state resistance R_{DS2} of MESFET 201 as a function of gate drive V_{G2}. Curve 211 illustrates the total resistance (R_{DS2}+R_{DS1}) of the cascode combination of MOSFET 202 and MESFET 201 as a function of MESFET gate drive V_{GS2} assuming a constant gate voltage V_{GS1} is used to bias MOSFET 202. Depending on the size and active gate width of both devices, the total resistance of the cascode switch may be increased or decreased as needed.

Ideally MESFET 201 should be made only slightly bigger than required to meet its required on-resistance and to minimize its gate charge and capacitance since it is the only device switching at the high frequency. In many applications, a usefully low value of on-resistance is in the range of typically several hundred milliohms or less, occupying an area of under 1 mm².

If a higher-current must be delivered, MESFET 201 can be oversized to decrease its resistance with minimal adverse impact to its input capacitance, gate charge, and gate-drive-related switching losses. The drain leakage does however increase in proportion to the MESFET's channel width. The use of large gate width low resistance MESFETs in a converter makes the need for a MOSFET cascode switch all the more critical to suppress leakage when the converter is not operating.

The size of MOSFET 202 can be increased to reduce its on-resistance without adversely impacting off-state leakage, e.g. with resistances in the range of 0.5 ohms to as low as several milliohms. The MOSFET on-resistance can be adjusted without adversely impacting gate drive losses in the switching converter since the MOSFET is turned-on and turned-off infrequently, at a frequency substantially less than the clock rate driving the gate of MESFET 201. The MOSFET may be manufactured using a lateral or a vertical process technology, including trench gated vertical power MOSFETs.

The gate voltage V_{GS1} driving MOSFET 202 is supplied by a separate gate buffer since the gate drive requirements of the MESFET and MOSFET differ in voltage and frequency. Accordingly, the devices should not be driven with the same gate buffer, but instead have separate gate buffers ideally powered from differing voltages. In the event that only a single power source is available, MOSFET 202 must be increased in size to adequately conduct to start the boost converter operating, and then thereafter MOSFET conduction losses can be minimized by powering its gate from the converter's output rather than from the battery directly.

The gates of the two devices should be driven independently since the voltage needed to fully enhance MOSFET 202 is much higher than the gate drive needed for MESFET 201, typically two to five times greater. Specifically, since the turn-on voltage of MESFET 201 is very low, generally well under one volt and typically around 0.5V, it may be powered by either the output or the battery directly. In a boost converter, powering the MESFET from the battery directly offers the benefit of lower gate drive losses since excess gate drive only leads to increased power losses and unwanted MESFET gate current. The gate drive for MOSFET 202 should be greater, ideally over 3V and even 5V as needed. In a preferred embodiment, operation in a DC/DC converter switches MESFET 201 on and off at a high frequency while switching of MOSFET 202 occurs at a low frequency, essentially to serve as a circuit enable (shut-off switch) to minimize leakage in long durations of off-time.

FIG. 6D illustrates an alternative cascode connection 215 where N-channel MOSFET 216 has its source connected to MESFET 218 rather than drain connected in cascode 200 as shown in FIG. 6A. Both cascode configurations are able to suppress series off-state leakage by shutting off the MOSFET. The avalanche voltage of this device, like that of cascode 200 is theoretically the sum of the MESFET and MOSFET avalanche voltages, but during a voltage transient, will distribute the drain voltage in proportion to the capacitance ratio of the devices. Depending on the duration, the more fragile MESFET may be damaged if excess voltage drives it deep into avalanche breakdown. The MOSFET's intrinsic diode 217 therefore does not guarantee protection of MESFET 218 under every circumstance, but has affords a greater degree of protection if MOSFET 216 is chosen to have an avalanche voltage greater than the maximum expected voltage in the application.

An alternative implementation of a cascode MOSFET-MESFET switch circuit is shown in FIG. 6E where P-channel MOSFET 221 (with its intrinsic diode 222) is used in place of an N-channel to control the leakage of the N-channel power MESFET 223. Such a configuration is useful when the cascode switch is utilized as a high-side switch (i.e., connected to the positive input voltage of a converter) or as a floating device (i.e., not connected to ground) since P-channel MOSFET 221 can easily be turned on by biasing its gate G₁ negative with respect to its source. The N-channel MESFET still requires a floating gate drive circuit since its proper operation requires its gate G₂ is biased to a voltage more positive than its source.

An inverted version of the high-side cascode switch is shown in FIG. 6F. In this version cascode switch 225 comprises series connected P-channel MOSFET 226 (and its intrinsic diode 227) and N-channel MESFET 228 except that the source of P-channel MOSFET 226 is connected to MESFET 228 rather than its drain. Like cascode 220, inverted cascode switch 225 is generally easier to drive in applications where the cascode switch is used as a high-side or floating device.

In Buck converters, the P-channel cascode device is preferred as a high-side switch while in boost converters it is best employed as the synchronous rectifier device.

### Protected Cascode MESFET-MOSFET Switch

FIG. 7 illustrates the leakage and avalanche current conduction mechanisms in the cross sectional view of MESFET 230 fabricated to exhibit normally-off behavior with a positive threshold voltage and a low off-state drain-leakage characteristic. The mesa structure comprising an N—GaAs layer 233 located atop a semi-insulating (SI) GaAs substrate 231 where the top of said GaAs substrate may comprise a sandwich of P-N junctions or alternating materials to further suppress substrate leakage. Included in epi layer 233 is trench gate 234 with Schottky gate metal 235 along with source and drain N+ regions 232.

In the off condition, MESFET 230 with grounded gate and source terminals 238 and 237 has its drain 236 biased at a potential V_{DS} forming depletion region 239 and pinching off any drain-to-source current except for leakage I_{DSS}. The peak electric field is located somewhere along the semiconductor surface in the vicinity of the trench and the edge of the Schottky gate. This location exhibits electric field crowding, impact ionization, and at a sufficiently high electric fields, potentially damaging avalanche breakdown. This avalanche can also be considered as a two-dimensional breakdown of the gate-to-drain Schottky diode. To prevent unwanted avalanche breakdown and hot-carrier generation the maximum voltage present across the device must never be allowed to approach the avalanche point, even in during a momentary voltage transient.

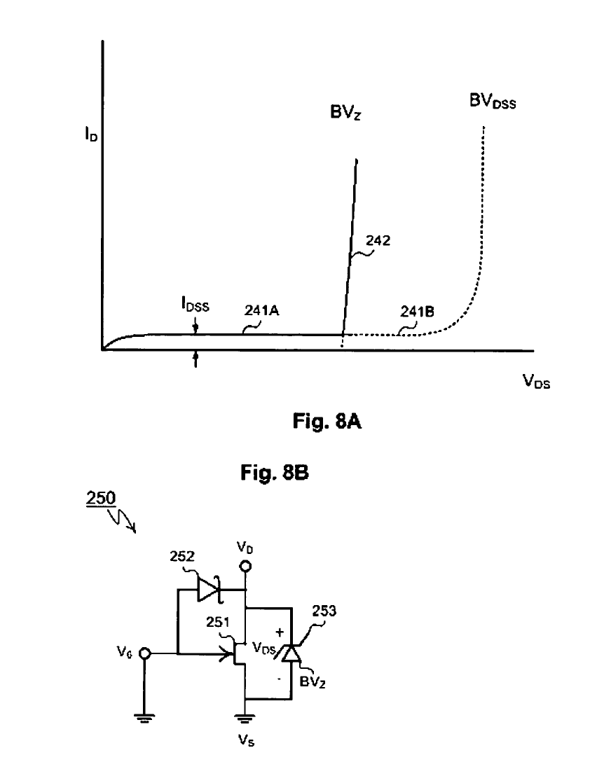

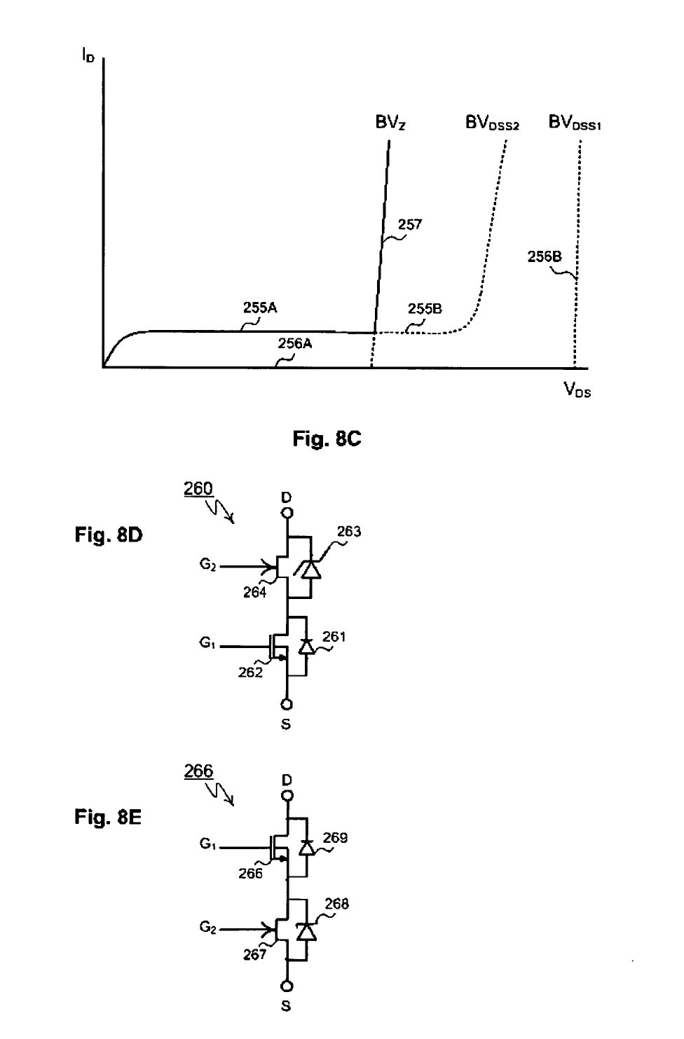

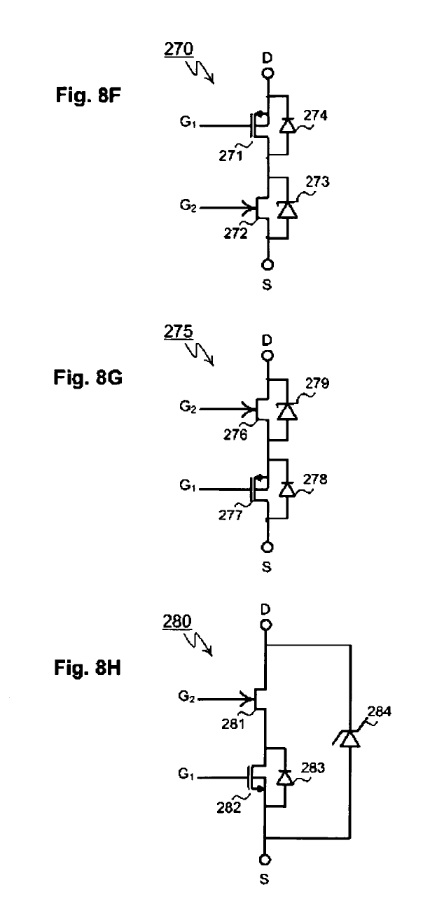

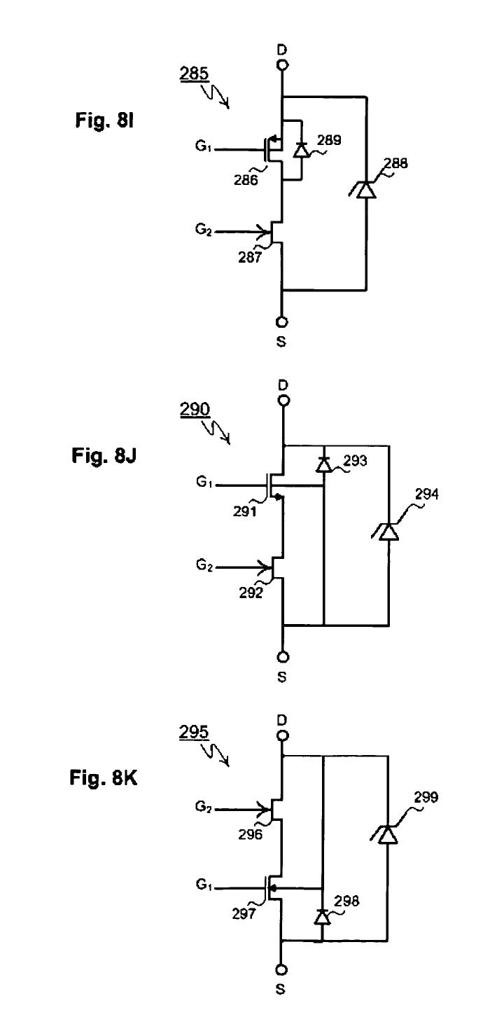

FIG. 8A illustrates the current voltage characteristics of a MESFET having I_{DSS} leakage 241A and avalanche breakdown 241B. To prevent potentially damaging avalanche in the device, the MESFET must be clamped by a Zener diode with a breakdown 242 of magnitude BV_{Z} sufficiently lower than the MESFET's breakdown voltage 241B to prevent any substantial impact ionization in the MESFET. This voltage guardband should be at least 2V and more ideally at least 5V. The combined characteristic of the clamped MESFET comprises the solid line portion of curves 241A and 242

The equivalent schematic of the voltage clamped MESFET in FIG. 8B is represented biased in its off-state by circuit 250 including MESFET 251, intrinsic gate-to-drain Schottky diode 252, and Zener clamp 253. In device 250, no mechanism to suppress leakage is represented other than the MESFET's intrinsic characteristics. In order to protect MESFET circuit 250, the clamp voltage BV_{Z} of Zener diode 253 is chosen to be less than the onset of avalanche or impact ionization in MESFET 251.

FIG. 8C illustrates the current-voltage characteristics of the voltage-clamped cascode MESFET-MOSFET switch shown schematically as circuit 260 in FIG. 8D. Specifically, curves 255A and 255B respectively illustrate the leakage and breakdown characteristics of MESFET 264 in the absence of Zener diode 263 whenever MOSFET 262 is on. Conversely curves 256A and 256B respectively illustrate the leakage and breakdown characteristics of MOSFET 262 whenever MESFET 264 is on. Breakdown 255B, having a voltage BV_{DSS2}, represents the avalanche voltage of MESFET 264 (a potentially damaging condition) while voltage BV_{DSS1} represents the drain-to-source breakdown of MOSFET 262 with its robust intrinsic drain-to-body diode 261. The addition of Zener clamp diode 263 limits the maximum voltage across MESFET 264 to the voltage BV_{Z} as shown by curve 257 whenever MOSFET 262 is on, as shown by the solid portion of curves 255A and 257.

Zener breakdown voltage is chosen to be less than the avalanche voltage or the onset of impact ionization in MESFET 264, i.e. where BV_{Z}<BV_{DSS2}, in order to protect the less robust MESFET from potential damage. In the case that both MESFET 264 and MOSFET 262 are biased into an “off” condition, the theoretical breakdown voltage of the device is (BV_{DSS1}+BV_{Z}), but because of the capacitive divider effect during transients either device may be driven momentarily into avalanche. So long as Zener 263 is present, MESFET 264 remains protected.

A variant of Zener clamped cascode switch 260 is the clamped cascode switch 265 of FIG. 8E comprising floating N-channel MOSFET 266 with intrinsic diode 269 with its source connected to MESFET 267 and Zener clamp diode 268. Operation of cascode switch 266 is similar to circuit 260 except that the MESFET and MOSFET series connection has been reversed. Zener clamped cascode switch implementations can be used for any circuit switch topology including high side switches, low-side switches, and floating switching, but are especially convenient in low-side switch applications like the main switch in a boost converter.

Another variant of this approach useful for high side switches and floating devices includes the clamped cascode switch 270 of FIG. 8F comprising high-side P-channel MOSFET 271 with intrinsic diode 274 with its drain connected to MESFET 272 and Zener clamp diode 273. Similarly, a variant of this approach include the clamped cascode switch 275 of FIG. 8G comprising floating P-channel MOSFET 277 with intrinsic diode 278 with its drain connected to MESFET 276 and Zener clamp diode 279.

Another version of the clamped cascode MESFET-MOSFET switch of this invention is represented in the circuits shown in FIG. 8H and FIG. 8I. In circuit 280 Zener-clamp 284 is in parallel to the series combination of N-channel MESFET 281 and N-channel MOSFET 282. The maximum voltage of the cascode switch is then limited to the breakdown of Zener diode 284, i.e. BV_{Z}, regardless of whether MOSFET 282 is on or off. The value of BV_{Z} should be chosen to be less than the breakdown of MESFET 281 and less than the breakdown of the MOSFET's intrinsic diode 283, mathematically as BV_{Z}<BV_{DSS2} and BV_{Z}<BV_{DSS1} respectively. Such a Zener clamped cascode switch has the same breakdown voltage independent of which switch is on or off. Strictly speaking, the criteria that the Zener breaks down at a voltage less than the MOSFET's avalanche voltage is not required so long as the MOSFET is relatively avalanche rugged and that the criteria BV_{Z}<BV_{DSS2} is strictly observed.

Similarly, in high-side or floating cascode switch circuit 285 shown in FIG. 8I, Zener-clamp 288 is in parallel to the series combination of N-channel MESFET 287 and P-channel MOSFET 286. The maximum voltage of the cascode switch is then limited to the breakdown of Zener diode 288, i.e. BV_{Z}, regardless of whether MOSFET 286 is on or off. The value of BV_{Z} should be chosen to be less than the breakdown of MESFET 287 and optionally less than the breakdown of the MOSFET's intrinsic diode 289, mathematically as BV_{Z}<BV_{DSS2} and BV_{Z}<BV_{DSS1} respectively. In other words, whether the MESFET is connected above or below the MOSFET has no impact on the breakdown characteristics of this approach.

In the prior examples, the source-to-body of the MOSFET is shorted, resulting in an anti-parallel source-to-drain diode (structurally comprising the MOSFET's gate-to-drain diode). Another method to implement a Zener clamped cascode switch is shown in FIG. 8J and in FIG. 8K which does not employ a MOSFET source-to-body short. Specifically, in circuit 290 N-channel MOSFET 291 has its source connected to the drain of N-channel MESFET 292 while the MOSFET's body is connected to the MESFET's source. The drain-to-body diode intrinsic to MOSFET 291 then acts as a diode clamp in parallel with the series combination of MOSFET 291 and MESFET 292. Provided the breakdown of diode 293 is lower than the breakdown of MESFET 292, i.e. BV_{DSS1}<BV_{DSS2}, the MESFET is protected. If the MOSFET's breakdown is not lower than the MESFET, then Zener diode 294 may be added, provided that the Zener voltage is lower than the MESFET's breakdown voltage BV_{Z}<BV_{DSS2}.

Similarly in circuit 295 P-channel MOSFET 297 has its source connected to the drain of N-channel MESFET 296 while the MOSFET's body is connected to the MESFET's source. The drain-to-body diode intrinsic to MOSFET 298 then acts as a diode clamp in parallel with the series combination of MOSFET 297 and MESFET 296. Provided the breakdown of diode 298 is lower than the breakdown of MESFET 296, i.e. BV_{DSS1}<BV_{DSS2}, the MESFET is protected. If the MOSFET's breakdown is not lower than the MESFET, then Zener diode 299 may be added, provided that the Zener voltage is lower than the MESFET's breakdown voltage BV_{Z}<BV_{DSS2}.

### Cascode MESFET-MOSFET Boost Converters

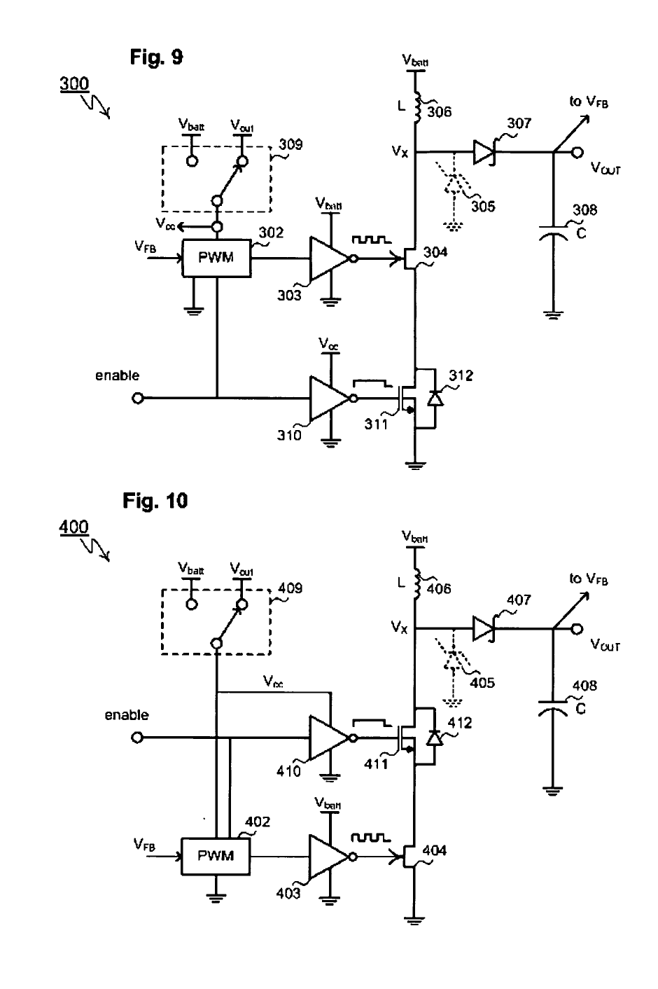

FIG. 9 illustrates an improved switching converter 300 using the MESFET-MOSFET cascode switch instead of a power MOSFET. As in the prior art circuit, the output of PWM control circuit 302 drives gate-buffer 303 which in turn drives the input of the power device, in this case N-channel MESFET 304. PWM circuit 302 is powered from either the battery voltage or the output voltage, whichever one is higher, through the switching action of selector switch function 309. Unlike in the prior art circuit, however, gate buffer 303 is powered from the battery, not from the converter's output. By using a MESFET switch instead of a power MOSFET, the 1V battery is adequate to fully enhance MESFET 304 into its low-resistance “on” state. By powering the gate drive off the battery directly (instead of powering off the output), no efficiency loss from re-using output power is manifest and efficiency is improved

The drain of MESFET 304 controls the average current through inductor 306 which also powers the output and filter capacitor 308 through Schottky diode 307. Unlike using the prior art power MOSFET as a switch, MESFET 304 has no anti-parallel diode intrinsic to its device structure and cannot safely survive high voltages, even for short durations. The cathode of Zener diode 305 as shown is connected in parallel with the series combination of MESFET 304 and MOSFET 311. The Zener is added to protect the drain of MESFET 304 from any Vx voltage unsafe for its operation. Zener 305 must be chosen to have a breakdown higher than a voltage Vx equal to the output voltage plus the forward drop of Schottky diode 307, but lower than the avalanche breakdown of MESFET 304. Alternatively, Zener 305 may be connected in parallel to MESFET 304.

As described in reference to FIG. 6A, the problem of MESFET 304 is that it may leak current in the off condition, thereby discharging the battery. To avoid this problem, converter 300 has added an N-channel MOSFET 311 to shut off the leakage. An inverter 310 drives the gate through MOSFET 311. Diode 312 is part of the transistor connected to the MOSFET 311.

FIG. 10 illustrates an improved switching converter 400 using a MESFET switch instead of a power MOSFET. As in the prior art circuit, the output of PWM control circuit 402 drives gate-buffer 403 which in turn drives the input of the power device, in this case N-channel MESFET 404. PWM circuit 402 is powered from either the battery voltage or the output voltage, whichever one is higher, through the switching action of selector switch function 409. Unlike in the prior art circuit, however, gate buffer 403 is powered from the battery, not from the converter's output. By using a MESFET switch instead of a power MOSFET, the 1V battery is adequate to fully enhance MESFET 404 into its low-resistance “on” state. By powering the gate drive off the battery directly (instead of powering off the output), no efficiency loss from re-using output power is manifest and efficiency is improved

The drain of MESFET 404 controls the average current through inductor 406 which also powers the output and filter capacitor 408 through Schottky diode 407. Unlike using the prior art power MOSFET as a switch, MESFET 404 has no anti-parallel diode intrinsic to its device structure and cannot safely survive high voltages, even for short durations. The cathode of Zener diode 405 as shown is connected in parallel with the series combination of MESFET 404 and MOSFET 411. The Zener is added to protect the drain of MESFET 404 from any Vx voltage unsafe for its operation. Zener 405 must be chosen to have a breakdown higher than a voltage Vx equal to the output voltage plus the forward drop of Schottky diode 407, but lower than the avalanche breakdown of MESFET 404. Alternatively, Zener 405 may be connected in parallel to MESFET 304.

While the boost converter examples shown are described for applications using a 1V battery and to output some higher voltage, e.g. 5V, the same circuits can be used with high input or output voltages provided component voltage ratings are adjusted accordingly. Specifically, the breakdown voltage of the MESFET and its Zener clamp cannot be lower than the boost converter's maximum output voltage plus one forward biased diode drop (plus some guardband).

The Zener clamp must also be chosen to breakdown before the MESFET avalanches or exhibits substantial impact ionization. For example, if a twelve volt output is desired, the Zener clamp would be chosen to be slightly higher, e.g. at 15V and the MESFET would need to exhibit a BV_{DSS} in excess of the Zener voltage, e.g. at 19V. Voltage selector circuitry 309 or 409 may also need to include a step down linear regulator or voltage clamp so not to drive PWM circuits 302 or 402 with too much voltage.

Higher input voltages may also be used provided that the gate drive of MESFET 304 or 404 is limited by gate buffer 303 or 403, and that the maximum operating voltage of the circuitry and the gate of MOSFET 311 or 411 are not exceeded.

### Cascode MESFET-MOSFET Synchronous Boost Converters

As described previously in FIG. 6, MESFET leakage in the off-state can adversely impact battery life during times where the switching converter is shutdown, i.e. in a standby mode. Microampere level leakage currents through a MESFET can gradually discharge a battery, especially if the product is seldom used. Using a cascode configured MOSFET-MESFET device-pair as the converter's main switch, or for the synchronous rectifier, eliminates these undesirable leakage currents.

FIG. 11 illustrates an improved switching converter using a cascode MESFET-MOSFET switch instead of a power MOSFET for both the converter's main switch and the synchronous rectifier. As in the prior art circuit, the output of PWM control circuit 502 drives break-before-make buffer 512, whose outputs drive MESFET gate buffers 503 and 511. Gate-buffer 503 drives the input of the converter's main switch, in this case N-channel MESFET 504. PWM circuit 502 is powered from either the battery voltage or the output voltage, whichever one is higher, through the switching action of selector switch function 509. Unlike in the prior art circuit, however, gate buffer 503 is powered from the battery, not from the converter's output. By using a MESFET switch instead of a power MOSFET, the 1V battery is adequate to fully enhance MESFET 504 into its low-resistance “on” state. By powering the gate drive off the battery directly (instead of powering off the output), no efficiency loss from re-using output power is manifest and efficiency is improved

Gate-buffer 522 controls the converter's synchronous rectifier, in this case N-channel MESFET 510. Gate buffer 522 is powered from the voltage Vx, not from the converter's output or directly from the battery. By using a MESFET switch instead of a power MOSFET, the 1V battery is adequate to fully enhance MESFET 510 into its low-resistance “on” state.

Elimination of leakage through MESFET 504 is provided by N-channel MOSFET 521, which remains on during normal converter operation and is switched off only during sleep mode by an enable signal driving inverter 520 whenever PWM circuit 502 is not operating. Since MOSFET 521 is switched at a low frequency compared to MESFET 504, its size may be increased to reduce its on-resistance without adversely impacting switching losses. Gate buffer 520 is powered by the highest available voltage, Vcc, as supplied by the output of selector circuit 509.

Elimination of leakage through synchronous rectifier MESFET 510 is provided by P-channel MOSFET 523, which remains on during normal converter operation and is switched off only during sleep mode by an enable signal driving inverter 522 whenever PWM circuit 502 is not operating. Since MOSFET 523 is switched at a low frequency compared to MESFET 510, its size may be increased to reduce its on-resistance without adversely impacting switching losses. Gate buffer 522 is powered by the highest available voltage, Vcc, as supplied by the output of selector circuit 509.

The drain of MESFET 504 controls the average current through inductor 506 which also powers the output and filter capacitor 508 through Schottky diode 507 and the synchronous rectifier cascode switch comprising MESFET 510 and MOSFET 523. Unlike using the prior art power MOSFET as a switch, MESFET 504 has no anti-parallel diode intrinsic to its device structure and cannot safely survive high voltages, even for short durations. The cathode of Zener diode 505 as shown is connected in parallel with MESFET 504. The Zener is added to protect the drain of MESFET 504 from any Vx voltage unsafe for its operation. Zener 505 must be chosen to have a breakdown higher than the output voltage plus the forward drop of Schottky diode 507, but lower than the avalanche breakdown of MESFET 504.

Since Schottky diode 507 is in parallel with the series connected cascode switch comprising MESFET 510 and MOSFET 523, inductor current is delivered to the load through diode 507 whenever MESFET 510 is switched off.

By using a cascode MESFET-MOSFET pair as a synchronous rectifier, MOSFET 523 can prevent leakage in MESFET 510 from discharging capacitor 508 whenever converter 500 is not operating. This converter circuit thereby prevents draining the battery and discharging the load during periods of non-operation. It should be noted that in the circuit as shown, diode 507 between the battery input voltage and the output Vout remains forward biased. If a complete disconnection between the output and input is required, bidirectional blocking can be facilitated by connecting Schottky 507 in parallel with MESFET 510 and eliminating the source body short in MOSFET 523, thereby eliminating the MOSFET's intrinsic diode 524. In such cases the MOSFET's body should be connected a more positive potential such as Vcc.

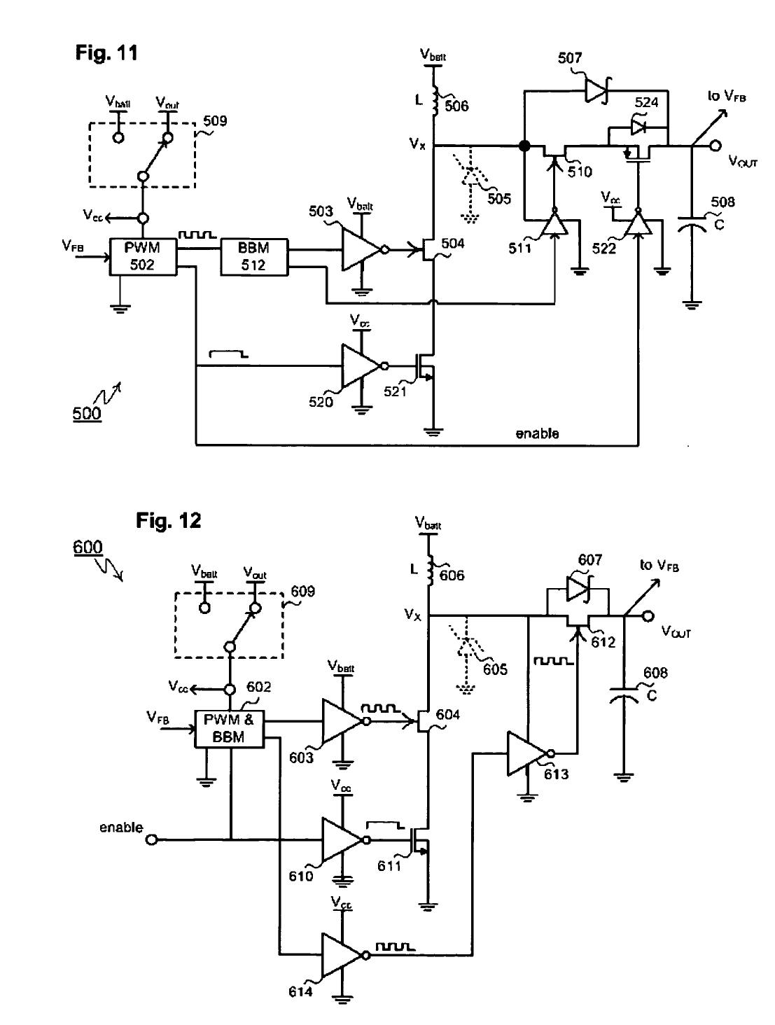

FIG. 12 illustrates an improved switching converter using a MESFET-MOSFET cascode switch instead of a power MOSFET. As in the prior art circuit, the output of PWM control circuit 602 drives gate-buffer 603 which in turn drives the input of the power device, in this case N-channel MESFET 604. PWM circuit 602 is powered from either the battery voltage or the output voltage, whichever one is higher, through the switching action of selector switch function 609. Unlike in the prior art circuit, however, gate buffer 603 is powered from the battery, not from the converter's output. By using a MESFET switch instead of a power MOSFET, the 1V battery is adequate to fully enhance MESFET 604 into its low-resistance “on” state. By powering the gate drive off the battery directly (instead of powering off the output), no efficiency loss from re-using output power is manifest and efficiency is improved.

Similar to the prior art, the drain of MESFET 604 controls the average current through inductor 606 which also powers the output and filter capacitor 608 through Schottky diode 607. Unlike using the prior art power MOSFET as a switch, MESFET 604 has no anti-parallel diode intrinsic to its device structure and cannot safely survive high voltages, even for short durations. The cathode of Zener diode 605 as shown is connected in parallel with MESFET 604. The Zener is added to protect the drain of MESFET 604 from any Vx voltage unsafe for its operation. Zener 605 must be chosen to have a breakdown higher than the output voltage plus the forward drop of Schottky diode 607, but lower than the avalanche breakdown of MESFET 604.

While MOSFET 611 in circuit 600 eliminates leakage current in MESFET 604 from discharging the battery input, it cannot prevent leakage from discharging output capacitor 608 as circuit 500 does.

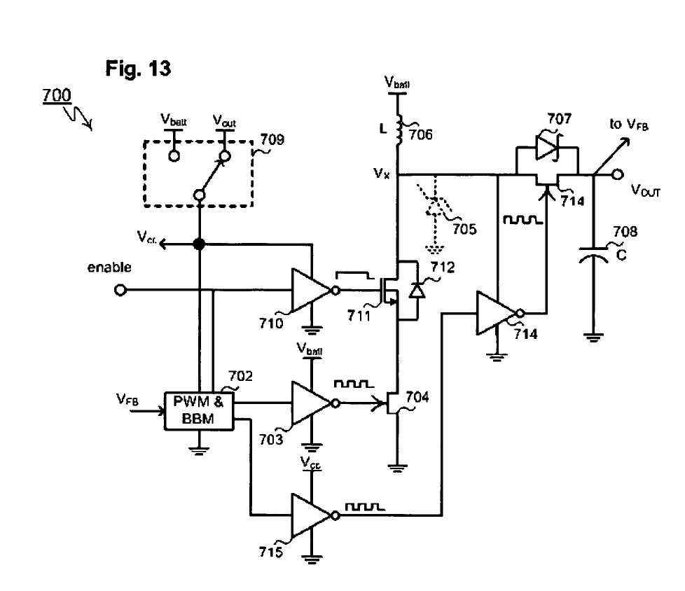

FIG. 13 illustrates an improved switching converter using a MESFET-MOSFET cascode switch instead of a power MOSFET. As in the prior art circuit, the output of PWM control circuit 702 drives gate-buffer 703 which in turn drives the input of the power device, in this case N-channel MESFET 704. PWM circuit 702 is powered from either the battery voltage or the output voltage, whichever one is higher, through the switching action of selector switch function 709. Unlike in the prior art circuit, however, gate buffer 703 is powered from the battery, not from the converter's output. By using a MESFET switch instead of a power MOSFET, the 1V battery is adequate to fully enhance MESFET 704 into its low-resistance “on” state. By powering the gate drive off the battery directly (instead of powering off the output), no efficiency loss from re-using output power is manifest and efficiency is improved.

Similar to the prior art, the drain of MESFET 704 controls the average current through inductor 706 which also powers the output and filter capacitor 708 through Schottky diode 707. Unlike using the prior art power MOSFET as a switch, MESFET 704 has no anti-parallel diode intrinsic to its device structure and cannot safely survive high voltages, even for short durations. The cathode of Zener diode 705 as shown is connected in parallel with MESFET 704. The Zener is added to protect the drain of MESFET 704 from any Vx voltage unsafe for its operation. Zener 705 must be chosen to have a breakdown higher than the output voltage plus the forward drop of Schottky diode 707, but lower than the avalanche breakdown of MESFET 704.

While MOSFET 712 in circuit 700 eliminates leakage current in MESFET 704 from discharging the battery input, it cannot prevent leakage from discharging output capacitor 708 as circuit 500 does.

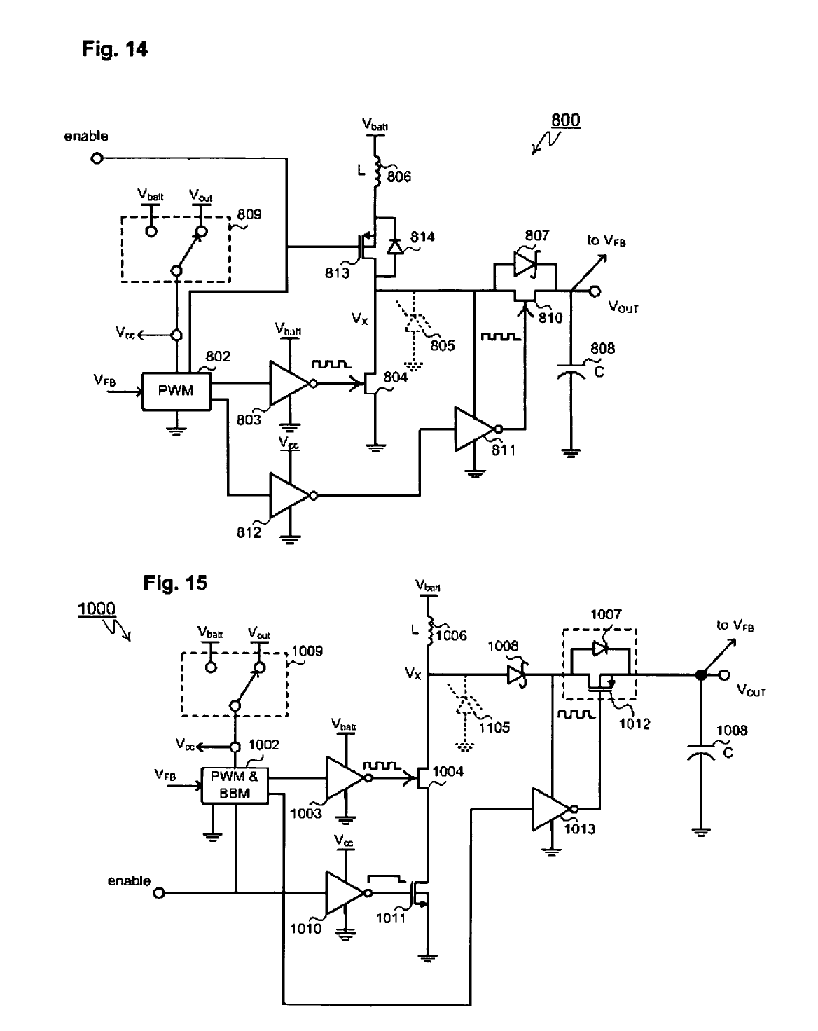

FIG. 14 illustrates an improved switching converter using a MESFET switch instead of a power MOSFET and including a means to disconnect the battery from any source of leakage. As in the prior art circuit, the output of PWM control circuit 802 drives gate-buffer 803 which in turn drives the input of the power device, in this case N-channel MESFET 804. PWM circuit 802 is powered from either the battery voltage or the output voltage, whichever one is higher, through the switching action of selector switch function 809. Unlike in the prior art circuit, however, gate buffer 803 is powered from the battery, not from the converter's output. By using a MESFET switch instead of a power MOSFET, the 1V battery is adequate to fully enhance MESFET 804 into its low-resistance “on” state. By powering the gate drive off the battery directly (instead of powering off the output), no efficiency loss from re-using output power is manifest and efficiency is improved

In this circuit, P-channel MOSFET 813 and its intrinsic diode 814 provide a means to disconnect the battery input from any form of leakage either through MESFET 804 or to the load, controlled by the enable input. Since MOSFET 813 is switched at a low frequency compared to MESFET 804, its size can be increased to reduce its on-resistance without adversely affecting switching losses and converter efficiency.

Similar to the prior art, the drain of MESFET 804 controls the average current through inductor 806 which also powers the output and filter capacitor 808 through Schottky diode 807. Unlike using the prior art power MOSFET as a switch, MESFET 804 has no anti-parallel diode intrinsic to its device structure and cannot safely survive high voltages, even for short durations. The cathode of Zener diode 805 as shown is connected in parallel with MESFET 804. The Zener is added to protect the drain of MESFET 804 from any Vx voltage unsafe for its operation. Zener 805 must be chosen to have a breakdown higher than the output voltage plus the forward drop of Schottky diode 807, but lower than the avalanche breakdown of MESFET 804.

While MOSFET 814 in circuit 800 eliminates leakage current in MESFET 804 or the output (load) from discharging the battery input, it cannot prevent leakage from discharging output capacitor 808 as circuit 500 does.

FIG. 15 illustrates an improved switching converter using a MESFET-MOSFET cascode switch instead of a power MOSFET. As in the prior art circuit, the output of PWM control circuit 1002 drives gate-buffer 1003 which in turn drives the input of the power device, in this case N-channel MESFET 1004. PWM circuit 1002 is powered from either the battery voltage or the output voltage, whichever one is higher, through the switching action of selector switch function 1009. Unlike in the prior art circuit, however, gate buffer 1003 is powered from the battery, not from the converter's output. By using a MESFET switch instead of a power MOSFET, the 1V battery is adequate to fully enhance MESFET 1004 into its low-resistance “on” state. By powering the gate drive off the battery directly (instead of powering off the output), no efficiency loss from re-using output power is manifest and efficiency is improved.

Similar to the prior art, the drain of MESFET 1004 controls the average current through inductor 1006 which also powers the output and filter capacitor 1008 through Schottky diode 1007. Unlike using the prior art power MOSFET as a switch, MESFET 1004 has no anti-parallel diode intrinsic to its device structure and cannot safely survive high voltages, even for short durations. The cathode of Zener diode 1005 as shown is connected in parallel with MESFET 1004. The Zener is added to protect the drain of MESFET 1004 from any Vx voltage unsafe for its operation. Zener 1005 must be chosen to have a breakdown higher than the output voltage plus the forward drop of Schottky diode 1008, but lower than the avalanche breakdown of MESFET 1004.

In circuit 1000, Schottky rectifier 1008 is placed in series with P-channel MOSFET 1012. Under normal operation MOSFET 1012 remains on and is switched off only when the converter is not operating, as controlled by gate buffer 1013. With MOSFET 1012 switched off, reversed biased diode 1007 prevents the battery from charging and discharging capacitor 1008.

Additional variations on the switching regulators described above are possible. If every switching regulator is assumed to include a low-side switch and a high-side switch the following combinations are applicable for implementing a boost converter:
1. low-side switch: N-channel MESFET, high-side switch: Schottky diode
2. low-side switch: N-channel MESFET, high-side switch: N-channel MESFET.
3. low-side switch: N-channel MESFET, high-side switch: MESFET cascode switch.
4. low-side switch: N-channel MESFET, high-side switch: MOSFET.
5. low-side switch: MOSFET, high-side switch: N-channel MESFET.
6. low-side switch: MOSFET, high-side switch: MESFET cascode switch.
7. low-side switch: MESFET cascode switch, high-side switch: Schottky diode
8. low-side switch: MESFET cascode switch, high-side switch: MOSFET.
9. low-side switch: MESFET cascode switch, high-side switch: N-channel MESFET.
10. low-side switch: MESFET cascode switch, high-side switch: MESFET cascode switch.
11. Of these various boost converter topologies, combination (4), (5), (6) and (8) are not suitable for operation at very high frequencies due to the speed and efficiency limitations imposed by the power MOSFET.

What is claimed is:

1. A boost converter that includes a normally off N-channel MESFET switch that regulates the output of the converter.

2. The boost converter of claim 1 where the MESFET is clamped by a Zener diode.

3. The boost converter of claim 1 where the gate of the MESFET is powered by a gate drive buffer that is powered directly by a battery that serves as the input source to the converter.

4. The boost converter of claim 1 where the MESFET is controlled by a PWM control circuit that is powered by a battery that serves as the input source to the boost converter during startup and is powered from the output of the boost converter during normal operation.

5. The boost converter of claim 1 where the MESFET is made of GaAs.

6. A synchronous boost converter that includes:
a low-side switch implemented using a first N-channel MESFET where the first N-channel MESFET is normally off; and
a synchronous rectifier implemented using a second N-channel MESFET.

7. The synchronous boost converter of claim 6 where the low-side MESFET is clamped by a Zener diode.

8. The synchronous boost converter of claim 6 where the gate of the first N-channel MESFET is powered by a first gate drive buffer that is powered directly by a battery that serves as the input source to the converter.

9. The synchronous boost converter of claim 6 where the gate of the second N-channel MESFET is powered by a second gate drive buffer that is powered directly by a battery that serves as the input source to the converter.

10. The synchronous boost converter of claim 9 where the second gate drive buffer produces a voltage higher than the output voltage of the converter.

11. The synchronous boost converter of claim 9 that further comprises a PWM control circuit that is powered by the battery during startup and is powered from the output of the boost converter during normal operation.

12. The synchronous boost converter of claim 6 where the first and second gate drive buffers are controlled by a break-before-make (BBM) shoot-through protection circuit.

13. The synchronous boost converter of claim 6 where the MESFET is made of GaAs.

14. A cascode power switch comprising a MOSFET in series with a normally-off MESFET.

15. The cascode power switch of claim 14 where the MOSFET is N-channel.

16. The cascode power switch of claim 15 where the drain of the MOSFET connects to the source of the MESFET.

17. The cascode power switch of claim 15 where the source of the MOSFET connects to the drain of the MESFET.

18. The cascode power switch of claim 14 where the MOSFET is P-channel.

19. The cascode power switch of claim 18 where the drain of the MOSFET connects to the source of the MESFET.

20. The cascode power switch of claim 18 where the source of the MOSFET connects to the drain of the MESFET.

21. The cascode power switch of claim 14 where the MOSFET has a lower on-state resistance than the MESFET.

22. The cascode power switch of claim 14 that further comprises driver circuitry that switches the MESFET and MOSFET at two different frequencies with the switching frequency of the MOSFET being lower than the switching frequency of the MESFET.

23. The cascode power switch of claim 14 where the MOSFET and MESFET gates are driven by respective gate drive buffers.

24. The cascode power switch of claim 14 where the MESFET is made of GaAs.

25. A switch that comprises: a normally-off MESFET in parallel with a Zener diode, the Zener diode having an avalanche voltage that is lower than the avalanche voltage of the MESFET.

26. A clamped cascode switch comprising a series connection of a normally off MESFET and a MOSFET, where the MESFET is connected in parallel with a Zener diode, and where the Zener diode has an avalanche voltage lower than the avalanche voltage of the MESFET.

27. The clamped cascode switch of claim 26 where the source of the MESFET is connected to the drain of the MOSFET.

28. The clamped cascode switch of claim 26 where the drain of the MESFET is connected to the source of the MOSFET.

29. The clamped cascode switch of claim 26 where the MOSFET is N-channel.

30. The clamped cascode switch of claim 26 where the MOSFET is P-channel.

31. The clamped cascode switch of claim 26 where the MESFET is made of GaAs.

32. A clamped cascode switch comprising a series connection of a normally off MESFET and a MOSFET, where the series connected MESFET and MOSFET is connected in parallel with a Zener diode, and where the Zener diode has an avalanche voltage lower than the avalanche voltage of the MESFET.

33. The clamped cascode switch of claim 32 where the source of the MESFET is connected to the drain of the MOSFET.

34. The clamped cascode switch of claim 32 where the drain of the MESFET is connected to the source of the MOSFET.

35. The clamped cascode switch of claim 32 where the MOSFET is N-channel.

36. The clamped cascode switch of claim 32 where the MOSFET is P-channel.

37. The clamped cascode switch of claim 32 where the MESFET is made of GaAs.

38. A cascode switch comprising a series connection of a normally off N-channel MESFET and an N-channel MOSFET, where the source of N-channel MOSFET is connected to the drain of the MESFET, and where the body of the N-channel MOSFET is connected to the source of the MESFET; and where the MOSFET includes a drain-to-body diode.

39. The cascode switch of claim 38 where the avalanche voltage of the drain-to-body diode of the MOSFET is lower than the avalanche voltage of the MESFET.

40. The cascode switch of claim 38 where a Zener diode is connected in parallel to the series combination of the MESFET and the MOSFET with the cathode of the Zener diode connected to the drain of the N-channel MOSFET and the anode of the Zener diode connected to the source of the MESFET.

41. The cascode switch of claim 38 where the MESFET is made of GaAs.

42. A cascode switch comprising a series connection of a normally off N-channel MESFET and a P-channel MOSFET, where the source of P-channel MOSFET is connected to the drain of the MESFET, and where the body of the P-channel MOSFET is connected to the source of the MESFET; and where the MOSFET includes a drain-to-body diode.

43. The cascode switch of claim 42 where the avalanche voltage of the drain-to-body diode of the MOSFET is lower than the avalanche voltage of the MESFET.

44. The cascode switch of claim 42 where a Zener diode is connected in parallel to the series combination of the MESFET and the MOSFET with the cathode of the Zener diode connected to the source of the MESFET and the anode of the Zener diode connected to the drain of the P-channel MOSFET.

45. The cascode switch of claim 42 where the MESFET is made of GaAs.

46. A boost converter that includes a cascode switch comprising a series connected MESFET and MOSFET.

47. The boost converter of claim 46 where the MOSFET is an N-channel.

48. The boost converter of claim 46 where the MOSFET has its source grounded.

49. The boost converter of claim 46 where the MESFET has its source grounded.

50. The boost converter of claim 46 where a Zener diode is connected in parallel to the cascode switch.

51. The boost converter of claim 46 the gate of the MESFET is switched at a higher frequency than that of the MOSFET.

52. The boost converter of claim 46 where the MESFET is made of GaAs.

53. A synchronous boost converter that comprises a first MESFET switch with a grounded source and a synchronous rectifier comprising a second MESFET switch having neither its source nor its drain connected to ground.

54. The synchronous boost converter of claim 53 where the first and second MESFET switch are driven out of phase so that only one of them conducts at any one time.

55. The synchronous boost converter of claim 53 where the on-times of the first and second MESFET switches are determined by a pulse-modulation-modulation (PWM) control circuit.

56. The synchronous boost converter of claim 53 where a Zener diode is in parallel with first MESFET.

57. The synchronous boost converter of claim 53 where a Schottky diode is in parallel with second MESFET.

58. The synchronous boost converter of claim 53 where a first gate buffer limits the maximum gate voltage of the first MESFET to a voltage below which substantial gate current flows into the first MESFET.

59. The synchronous boost converter of claim 53 where a first gate buffer driving the gate of the first MESFET is powered from a battery that serves as the input source to the converter.

60. The synchronous boost converter of claim 53 where a second gate buffer drives the gate of the second MESFET to a voltage more positive than its source voltage.

61. The second gate buffer of claim 60 where the second gate buffer limits the maximum gate-to-source voltage of the second MESFET to a voltage below which substantial gate current flows into the second MESFET.

62. A synchronous boost converter that comprises a grounded cascode switch comprising a first N-channel MESFET and a N-channel MOSFET, and a synchronous rectifier comprising a second N-channel MESFET switch having neither its source nor its drain connected to ground.

63. The synchronous boost converter of claim 62 where the N-channel MOSFET has a grounded source and a drain connected to the source of the N-channel MESFET.

64. The synchronous boost converter of claim 62 where the first N-channel MESFET has a grounded source and a drain connected to the source of the N-channel MOSFET.

65. The synchronous boost converter of claim 62 where the first and second N-channel MESFETs are driven out of phase so that only one of them conducts at any one time.

66. The synchronous boost converter of claim 62 where the on-times of the first and second N-channel MESFET switches are determined by a pulse-width-modulation (PWM) control circuit.

67. The synchronous boost converter of claim 62 where a Zener diode is in parallel with the cascode MESFET-MOSFET switch.

68. The synchronous boost converter of claim 62 where a Schottky diode is in parallel with second N-channel MESFET.

69. The synchronous boost converter of claim 62 where a first gate buffer limits the maximum gate voltage of the first MESFET to a voltage below which substantial gate current flows into the first MESFET gate.

70. The synchronous boost converter of claim 62 where a first gate buffer driving the gate of the first MESFET is powered from a battery that serves as the input source to the converter.

71. The synchronous boost converter of claim 62 where a second gate buffer drives the gate of the second N-channel MESFET to a voltage more positive than its source voltage.

72. The second gate buffer of claim 71 where the second gate buffer limits the maximum gate-to-source voltage of the second N-channel MESFET to a voltage below which substantial gate current flows into the second MESFET.

73. The synchronous boost converter of claim 62 where the N-channel MESFET is biased into an on condition whenever the boost converter is operating and delivering power to its load.

74. The synchronous boost converter of claim 62 where the N-channel is biased into an off condition whenever the first and second MESFETs are not switching.

75. The synchronous boost converter of claim 62 where the first and second MESFETs switch at a higher frequency the N-channel MOSFET.

76. A synchronous boost converter that comprises a first N-channel MESFET with a grounded source and a P-channel MOSFET in series with an inductor, and a synchronous rectifier comprising a second N-channel MESFET switch having neither its source nor its drain connected to ground.

77. The synchronous boost converter of claim 76 where the P-channel MOSFET has a source connected to the inductor and a drain connected to the drain of first N-channel MESFET.

78. The synchronous boost converter of claim 76 where the P-channel MOSFET has a source connected to a battery that serves as the input source of the converter, and a drain connected to the inductor, where furthermore the inductor has a second terminal connected to the drain of first N-channel MESFET.

79. The synchronous boost converter of claim 76 where the first and second N-channel MESFETs are driven out of phase so that only one of them conducts at any one time.

80. The synchronous boost converter of claim 76 where the on-times of the first and second N-channel MESFET switches are determined by a pulse-width-modulation (PWM) control circuit.

81. The synchronous boost converter of claim 76 where a Zener diode is in parallel with the first MESFET.

82. The synchronous boost converter of claim 76 where a Schottky diode is in parallel with second MESFET switch.

83. The synchronous boost converter of claim 76 where a first gate buffer limits the maximum gate voltage of the first MESFET to a voltage below which substantial gate current flows into the first MESFET gate.

84. The synchronous boost converter of claim 76 where a first gate buffer driving the gate of the first MESFET is powered from the battery input to the converter.

85. The synchronous boost converter of claim 76 where a second gate buffer drives the gate of the second N-channel MESFET to a voltage more positive than its source voltage.

86. The synchronous boost converter of claim 85 where the second gate buffer limits the maximum gate-to-source voltage of the second N-channel MESFET to a voltage below which substantial gate current flows into the second MESFET.

87. The synchronous boost converter of claim 76 where the P-channel MOSFET is biased into an on condition whenever the boost converter is operating and delivering power to its load.

88. The synchronous boost converter of claim 76 where the P-channel MOSFET is biased into an off condition whenever the first and second MESFETs are not switching.

89. The synchronous boost converter of claim 76 where the first and second MESFETs switch at a higher frequency the P-channel MOSFET.

90. A synchronous boost converter that comprises a grounded cascode switch comprising an N-channel MESFET and a N-channel MOSFET, and a synchronous rectifier comprising a P-channel MOSFET switch having neither its source nor its drain connected to ground.

91. The synchronous boost converter of claim 90 where the N-channel MOSFET has a grounded source and a drain connected to the source of the N-channel MESFET.

92. The synchronous boost converter of claim 90 where the N-channel MESFET has a grounded source and a drain connected to the source of the N-channel MOSFET.

93. The synchronous boost converter of claim 90 where the N-channel MESFET and P-channel MOSFET driven out of phase so that only one of them conducts at any one time.

94. The synchronous boost converter of claim 90 where the on-times of the N-channel MESFET and P-channel MOSFET are determined by a pulse-width-modulation (PWM) control circuit.

95. The synchronous boost converter of claim 90 where a Zener diode is in parallel with the N-channel MESFET.

96. The synchronous boost converter of claim 90 where a Schottky diode is in parallel with P-channel MESFET.

97. The synchronous boost converter of claim 90 where a first gate buffer limits the maximum gate voltage of the MESFET to a voltage below which substantial gate current flows into the MESFET gate.

98. The synchronous boost converter of claim 90 where a first gate buffer driving the gate of the first MESFET is powered from a battery that serves as the input source to the converter.

99. The synchronous boost converter of claim 90 where the N-channel MOSFET is biased into an on condition whenever the boost converter is operating and delivering power to its load.

100. The synchronous boost converter of claim 90 where the N-channel MOSFET is biased into an off condition whenever the MESFETs and P-channel MOSFET are not switching.

101. The synchronous boost converter of claim 90 where the N-channel MESFET and P-channel MOSFET switch at a higher frequency the N-channel MOSFET.

102. A synchronous boost converter that comprises:
an inductor connected between a battery and a node Vx;
an N-channel MESFET;
a MOSFET; and
a control circuit, where the control circuit drives the MESFET and MOSFET out of phase so that the node Vx is alternately connected to ground and to an output node.
